(19) United States
(12) Patent Application Publication
(10) Pub. No.: US 2026/0354138 A1
(43) Pub. Date: Nov. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: I-Chang LEE, Hsinchu City (TW); Chen-Feng SU, Taipei City (TW); Lin-Ting LIN, Taichung (TW); Wei Hsiang CHAN, Hsinchu (TW); I-Hsin TSENG, Hsinchu County (TW); Jiann-Horng LIN, Hsinchu City (TW); Cheng-Hao YEH, Taichung City (TW)

(21) Appl. No.: 19/294,386

(22) Filed: Aug. 8, 2025

Related U.S. Application Data
(60) Provisional application No. 63/800,044, filed on May 5, 2025.

(51) Int. Cl. H10W 20/00; H10W 20/20

(52) U.S. Cl. CPC H10W 20/023; H10W 20/057; H10W 20/076; H10W 20/088; H10W 20/089; H10W 20/20

(57) ABSTRACT

A recess for a through-substrate interconnect structure is formed through an interconnect layer and into a substrate layer of a semiconductor device in a manner that decreases the sharpness of a transition angle in the sidewalls of the recess between the interconnect layer and the substrate layer. After etching the substrate layer to extend the recess into the substrate layer, a subsequent sidewall trimming operation is performed. The trimming operation may include a highly directional etch that is performed to flatten out the kink in the sidewalls, thereby decreasing the sharpness of the transition angle in the sidewalls of the recess between the interconnect layer and the substrate layer. The increased flatness of the sidewalls increases the coverage of a seed layer that is subsequently deposited on the sidewalls of the recess.

### CROSS-REFERENCE TO RELATED APPLICATION

This Patent Application claims priority to U.S. Provisional Patent Application No. 63/800,044, filed on May 5, 2025, and entitled “SEMICONDUCTOR DEVICE AND METHODS OF FORMATION.” The disclosure of the prior Application is considered part of and is incorporated by reference into this Patent Application.

### BACKGROUND

Various semiconductor device packing techniques may be used to incorporate one or more semiconductor dies into a semiconductor package. In some cases, semiconductor dies may be horizontally interconnected through an interposer. Additionally and/or alternatively, semiconductor dies may be arranged vertically in a semiconductor package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a semiconductor device described herein.

FIGS. 2A-2P are diagrams of an example implementation of forming a semiconductor device described herein.

FIG. 3 is a diagram of an example implementation of a semiconductor device described herein.

FIGS. 4A-4K are diagrams of an example implementation of forming a semiconductor device described herein.

FIG. 5 is a diagram of an example implementation of a semiconductor package described herein.

FIGS. 6A-6D are diagrams of an example implementation of forming a semiconductor package described herein.

FIG. 7 is a flowchart of an example process associated with forming a semiconductor device described herein.

FIG. 8 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To enable signals and/or power to be routed between the first and second interconnect layers, one or more through-substrate interconnect structures may be included through a substrate layer (e.g., a device layer or semiconductor layer) in which the integrated circuit devices are included. The through-substrate interconnect structure(s) (sometimes referred to as through-silicon vias or through-substrate vias (TSVs)) connect with one or more metallization layers in the first and second interconnect layers, and may be formed of electrically conductive metals such as copper (Cu) to achieve a low electrical resistance between the metallization layers in the first and second interconnect layers through the elongated conductive structure(s).

A through-substrate interconnect structure may be formed by forming a recess in and/or through the substrate layer, filling the recess with electrically conductive material, and then planarizing the through-substrate interconnect structure to remove excess electrically conductive material. Improved adhesion and gap-filling performance for the through-substrate interconnect structure may be achieved by first depositing a seed layer on the sidewalls and bottom surface of the recess, and then filling in the remaining area in the recess with material of the through-substrate interconnect structure using a bulk deposition technique such as physical vapor deposition (PVD) and/or electroplating, among other examples.

The process for forming the recess may include a complex set of etch operations for etching through different types of materials. For example, a recess for a through-substrate interconnect structure may first be formed through a frontside interconnect layer (which may involve etching through dielectric material) in a first etch operation, and then into a substrate layer (which may involve etching into semiconductor material) in a second etch operation. As the recess is etched into the substrate layer, lateral etching may occur in the substrate layer near the interconnect layer, which may result in a kink or ridge forming in the sidewalls of the recess at the transition between the interconnect layer and the substrate layer. This kink may correspond to a sharp transition angle between the interconnect layer and the substrate layer that occurs because of the lateral etching, and this kink may increase the likelihood that discontinuities are formed in the seed layer that is to be deposited on the sidewalls of the recess. Discontinuities in the seed layer may increase the likelihood of void formation in the through-substrate interconnect structure, which may increase the electrical resistance of the through-substrate interconnect structure.

In some implementations described herein, a recess for a through-substrate interconnect structure is formed through an interconnect layer and into a substrate layer of a semiconductor device in a manner that decreases the sharpness of a transition angle (e.g., a kink) in the sidewalls of the recess between the interconnect layer and the substrate layer. After the substrate layer is etched to extend the recess into the substrate layer, a subsequent sidewall trimming operation is performed. The trimming operation may include a highly directional (e.g., vertical) etch that is performed to trim the sidewalls of the recess at or near the transition between the interconnect layer and the substrate layer. The trimming operation flattens out the kink in the sidewalls, thereby decreasing the sharpness of the transition angle in the sidewalls of the recess between the interconnect layer and the substrate layer. The increased flatness of the sidewalls increases the coverage of a seed layer that is subsequently deposited on the sidewalls of the recess, which reduces the likelihood of void formation in the bulk material layer of the through-substrate interconnect structure that is subsequently deposited on the seed layer in the recess. The reduced likelihood of void formation may enable a low electrical resistance to be achieved for the through-substrate interconnect structure, thereby increasing the performance of the semiconductor device. As semiconductor processing nodes advance, and the sizes of through-substrate interconnect structures are reduced, the reduced likelihood of void formation may decrease the likelihood of discontinuity formation in the through-substrate interconnect structures of semiconductor devices, thereby increasing the yield of the semiconductor devices formed on a semiconductor substrate.

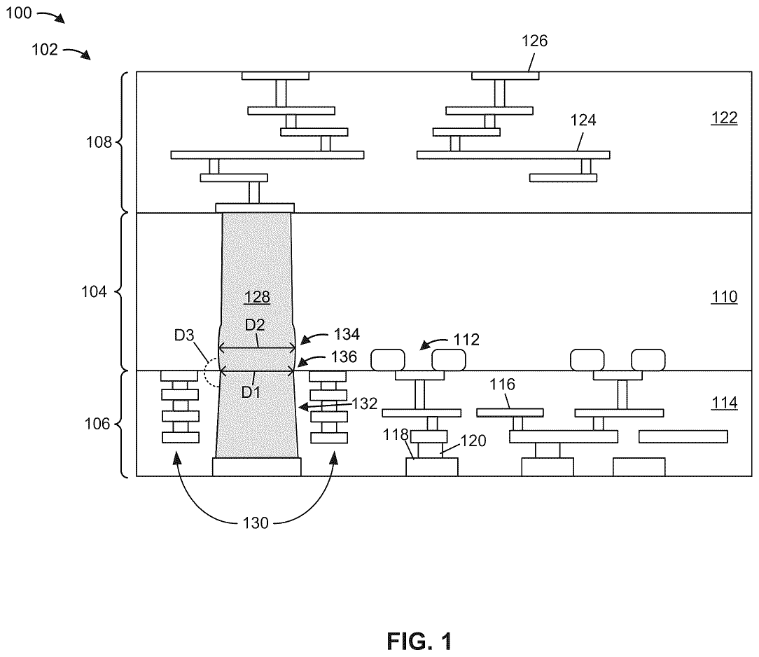

FIG. 1 is a diagram of an example implementation 100 of a semiconductor device 102 described herein. The semiconductor device may correspond to a semiconductor die that was manufactured on a substrate such as a semiconductor wafer. The semiconductor device 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor device 102 may include a memory die, an input/output (I/O) die, a pixel sensor die, and/or another type of semiconductor device. A memory die may include a static random access memory (SRAM) die, a dynamic random access memory (DRAM) die, a NAND die, a high bandwidth memory (HBM) die, and/or another type of memory die.

As shown in FIG. 1, the semiconductor device 102 may include a device layer 104, an interconnect layer 106 (e.g., a frontside interconnect layer) adjacent to a first side of the device layer 104 in the z-direction, and an interconnect layer 108 (e.g., a backside interconnect layer) adjacent to a second side of the device layer 104 in the z-direction. Thus, the interconnect layer 106, the device layer 104, and the interconnect layer 108 may be stacked and vertically arranged in the semiconductor device 102.

The device layer 104 may include a semiconductor layer 110, which may correspond to a portion of the semiconductor wafer on which the semiconductor device 102 was manufactured. Therefore, the semiconductor layer 110 may be referred to as the substrate layer of the semiconductor device 102. The semiconductor layer 110 may include a silicon (Si) layer, a layer formed of a material including silicon, a III-V compound semiconductor material layer such as gallium arsenide (GaAs), and/or or another type of semiconductor layer.

The device layer 104 may include one or more integrated circuit (IC) devices 112 in and/or on the semiconductor layer 110. The IC devices 112 may include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active IC devices. The IC devices 112 may be formed in and/or on the first side (e.g., the frontside) of the semiconductor layer 110 and may be electrically coupled to the interconnect layer 106 (e.g., the frontside interconnect layer) and/or the interconnect layer 108 (e.g., the backside interconnect layer).

The interconnect layer 106 may include one or more dielectric layers 114 and conductive structures 116 that interconnect the IC devices 112 and/or provide power to the IC devices 112. The conductive structures 116 of the interconnect layer 106 may be included in the one or more dielectric layers 114, and the dielectric layer(s) 114 may be arranged in a direction (e.g., the z-direction) that is approximately perpendicular to the semiconductor layer 110. The dielectric layer(s) 114 may include backend dielectric layers (e.g., interlayer dielectric (ILD) layers, intermetal dielectric (IMD) layers) and etch stop layers (ESLs) that are arranged in an alternating manner in the interconnect layer 106. The dielectric layer(s) 114 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The conductive structures 116 may be electrically coupled and/or physically coupled with one or more of the IC devices 112 in the device layer 104. The conductive structures 116 correspond to metal routing that enables signals and/or power to be provided to and/or from the IC devices 112. The conductive structures 116 may include a combination of conductive structures that extend primarily horizontally (e.g., in an x-direction and/or in a y-direction) in the interconnect layer 106 (e.g., trenches, conductive lines, metal wires) and that are interconnected by interconnect structures (e.g., vias) that extend primarily vertically (e.g., in the z-direction) in the interconnect layer 106. The conductive structures 116 may each include one or more electrically-conductive materials such as tungsten (W), cobalt (Co), ruthenium (Ru), titanium (Ti), aluminum (Al), copper (Cu), gold (Au), and/or a combination thereof, among other examples of electrically-conductive materials.

The conductive structures 116 of the interconnect layer 106 may be arranged in a vertical manner (e.g., in the z-direction) to facilitate electrical signals and/or power to be routed between the device layer 104 of the semiconductor device 102 and bonding pads 118 of the semiconductor device 102. The conductive structures 116 may be arranged in alternating layers of metallization layers (referred to as “M”-layers) and via layers (referred to as “V”-layers). Each metallization layer may include one or more conductive structures 116 laterally arranged in the interconnect layer 106, and each via layer may include one or more conductive structures 116 that interconnect the metallization layers in the interconnect layer 106.

As an example, a layer of interconnect structures that includes source/drain interconnects (VDs) and gate interconnects (VGs) may be located at the bottom of the interconnect layer 106 and may be coupled with the IC devices 112 in the device layer 104, a metal-0 (M0) layer may be located vertically adjacent and coupled to the layer of interconnect structures, a via-0 (V0) layer may be located vertically adjacent to and coupled with the M0 layer in the interconnect layer 106, a metal-1 (M1) layer may be located vertically adjacent to and coupled to the V0 layer in the interconnect layer 106, a via-1 (V1) layer may be located vertically adjacent to and coupled to the M1 layer in the interconnect layer 106, a metal-2 (M2) layer may be located vertically adjacent to and electrically coupled with the V1 layer in the interconnect layer 106, and so on. In some implementations, the interconnect layer 106 includes nine (9) stacked metallization layers (e.g., M0-M8). However, other quantities of stacked metallization layers are within the scope of the present disclosure.

As further shown in FIG. 1, the interconnect layer 106 may further include bonding vias 120 that electrically couple the bonding pads 118 to the conductive structures 116 of the interconnect layer 106. The bonding pads 118 and the bonding vias 120 may each extend through one or more of the dielectric layers 114, and may include one or more electrically-conductive materials such as tungsten (W), cobalt (Co), ruthenium (Ru), titanium (Ti), aluminum (Al), copper (Cu), gold (Au), and/or a combination thereof, among other examples of electrically conductive metals.

On the backside of the device layer 104, the interconnect layer 108 (e.g., the backside interconnect layer or bonding layer) may include a combination of dielectric layers 122 and conductive structures 124 that are arranged in a similar manners as the dielectric layers 114 and the conductive structures 116 in the interconnect layer 106 (e.g., the frontside interconnect layer). Connection structures 126 may also be included in the interconnect layer 108 and may include bonding pads, solder balls, contact pads, contact pins, and/or another type of connection structures that facilitate connecting the semiconductor device 102 to an external structure. The connection structures 126 may be electrically coupled and/or physically coupled to one or more conductive structures 124 in the interconnect layer 108.

As further shown in FIG. 1, the interconnect layer 106 (e.g., the frontside interconnect layer) and the interconnect layer 108 (e.g., the backside interconnect layer or bonding layer) may be electrically connected together by one or more through-substrate interconnect structures 128. The through-substrate interconnect structure(s) 128 may extend vertically (e.g., in the z-direction) between the semiconductor layer 110 of the semiconductor device 102, and may include a pillar, a via, a through-silicon via (TSV), and/or another type of elongated conductive structure that is elongated in the z-direction. A through-substrate interconnect structure 128 may include one or more electrically-conductive materials such as copper (Cu), tungsten (W), and/or titanium (Ti), among other examples.

A first end of a through-substrate interconnect structure 128 may extend into and/or through the interconnect layer 106, and may be electrically coupled and/or physically coupled to one or more conductive structures 116 in the interconnect layer 106. Alternatively, the first end of the through-substrate interconnect structure 128 may be electrically coupled and/or physically coupled to a bonding pad 118 in the interconnect layer 106. The section of the through-substrate interconnect structure 128 that extends through the interconnect layer 106 may be laterally surrounded by a guard ring structure 130 that includes a plurality of interconnected layers of conductive structures 116. The guard ring structure 130 may be included around the through-substrate interconnect structure 128 to provide shielding for other conductive structures 116 in the interconnect layer 106 and/or to protect other layers and/or structures in the interconnect layer 106 from being etched during formation of the recess for the through-substrate interconnect structure 128.

A second end (e.g., vertically opposing the first end) of the through-substrate interconnect structure 128 may extend to the interconnect layer 108 and may be electrically coupled and/or physically coupled to one or more conductive structures 124 in the interconnect layer 108. In some implementations, the second end of the through-substrate interconnect structure 128 may extend into one or more dielectric layers 122 of the interconnect layer 108. In some implementations, the second end of the through-substrate interconnect structure 128 may be approximately co-planar with a backside surface of the semiconductor layer 110.

As further shown in FIG. 1, a through-substrate interconnect structure 128 may have a cross-sectional profile that results from the processes and techniques that were used to form the recess in which the through-substrate interconnect structure 128 was formed. As an example, a tapered section 132 of the through-substrate interconnect structure 128 that extends through the interconnect layer 106 may have tapered sidewalls such that the lateral width of the through-substrate interconnect structure 128 increases from a bottom of the interconnect layer 106 (facing the semiconductor layer 110) to a top of the interconnect layer 106 (where the bonding pads 118 are located). As another example, the through-substrate interconnect structure 128 may have a bowed section 134 in the semiconductor layer 110. The bowed section 134 may be a localized section of the through-substrate interconnect structure 128 where the lateral width of the through-substrate interconnect structure 128 in the semiconductor layer 110 is greater than other sections of the through-substrate interconnect structure 128 in the semiconductor layer 110. The bowed section 134 may be formed as a result of etching the semiconductor layer 110 from the frontside of the semiconductor layer 110. Since the frontside of the semiconductor layer 110 is exposed to etchants for a longer duration than the bottom of the recess in the semiconductor layer 110, some lateral expansion occurs at the top of the semiconductor layer 110, resulting in formation of the bowed section 134.

As further shown in FIG. 1, the bowed section 134 may be located at or near a transition 136 between the interconnect layer 106 and the semiconductor layer 110. A transition between the tapered section 132 of the through-substrate interconnect structure 128 in the interconnect layer 106 and the bowed section 134 of the through-substrate interconnect structure 128 in the semiconductor layer 110 is located at the transition 136 between the interconnect layer 106 and the semiconductor layer 110. The transition between the tapered section 132 and the bowed section 134 may be referred to as a kink, which corresponds to a transition between the sidewall profile of the tapered section 132 and a sidewall profile of the bowed section 134.

Because the lateral width (indicated in FIG. 1 as a dimension D1) of the through-substrate interconnect structure 128 at the transition 136 may be less than the lateral width (indicated in FIG. 1 as a dimension D2) of the through-substrate interconnect structure 128 at an approximate center height of the bowed section 134, an outward sidewall angle (indicated in FIG. 1 as a dimension D3) between the sidewall profile of the tapered section 132 and the sidewall profile of the bowed section 134 may be less than approximately 180 degrees.

If the outward sidewall angle is too small (e.g., approximately 140 degrees or less), the transition between the sidewall profile of the tapered section 132 and the sidewall profile of the bowed section 134 (e.g., the kink) may be sufficiently abrupt to reduce the gap-filling performance at the transition 136. The reduction in gap-filling performance for depositing the material of the through-substrate interconnect structure 128 in the recess may result in formation of voids and other discontinuities in the through-substrate interconnect structure 128, which may increase the electrical resistance of the through-substrate interconnect structure 128.

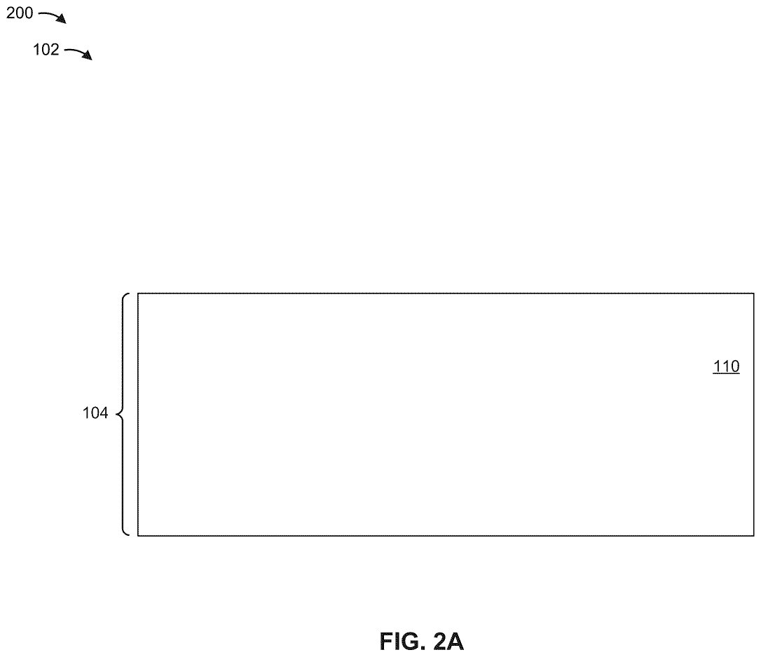

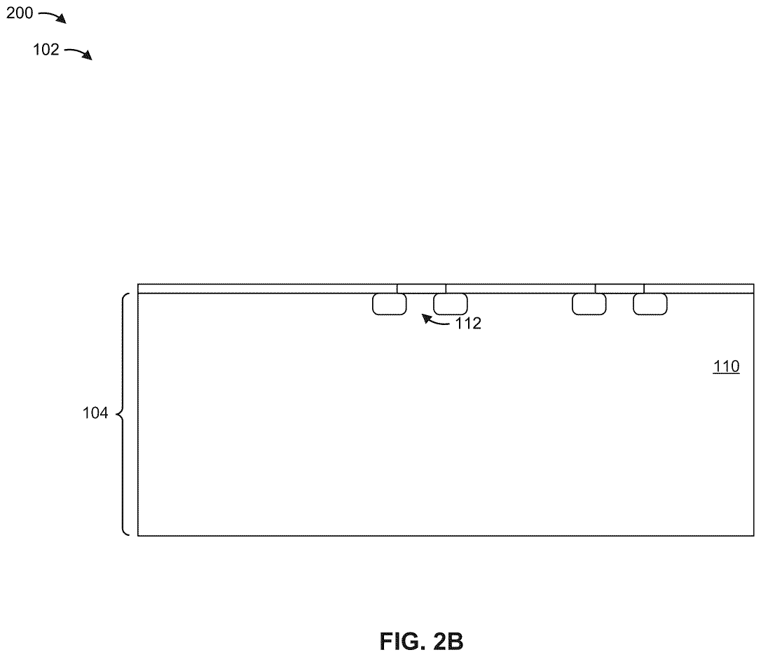

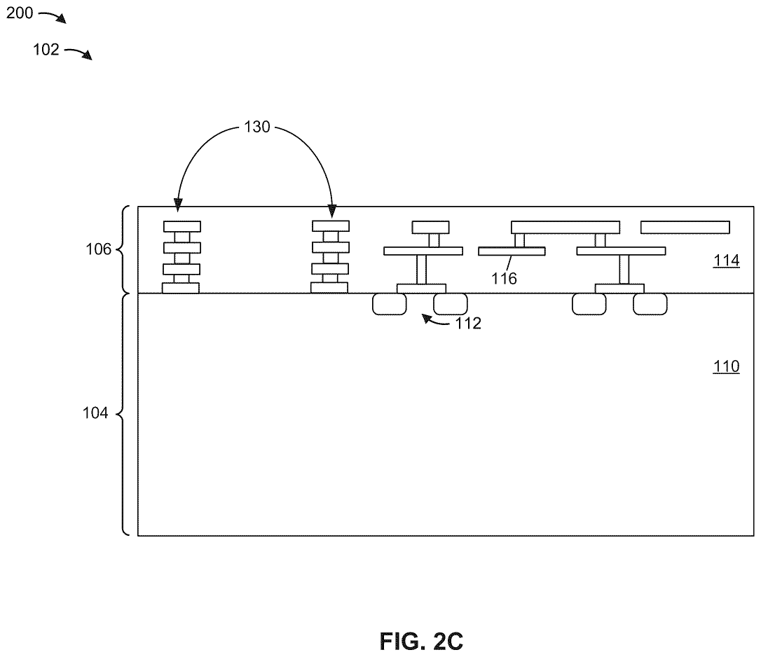

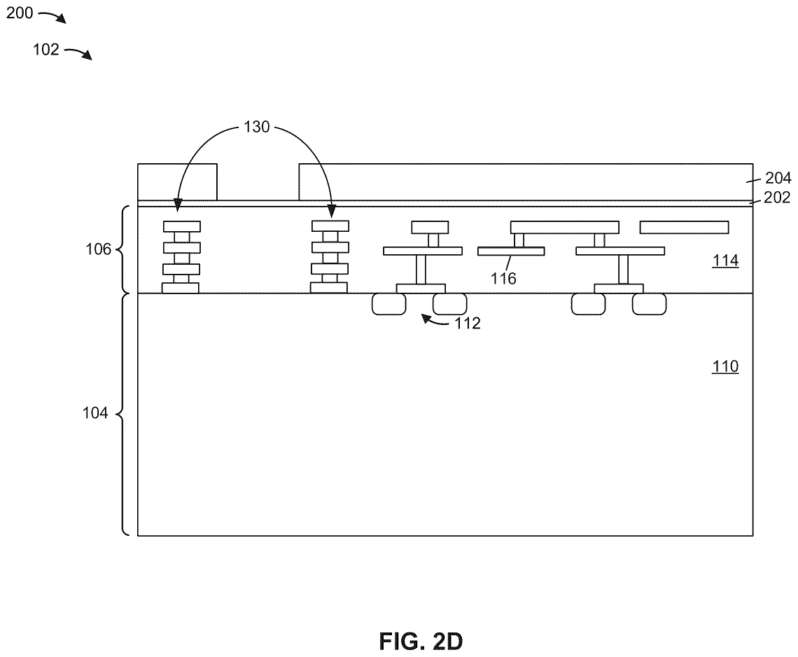

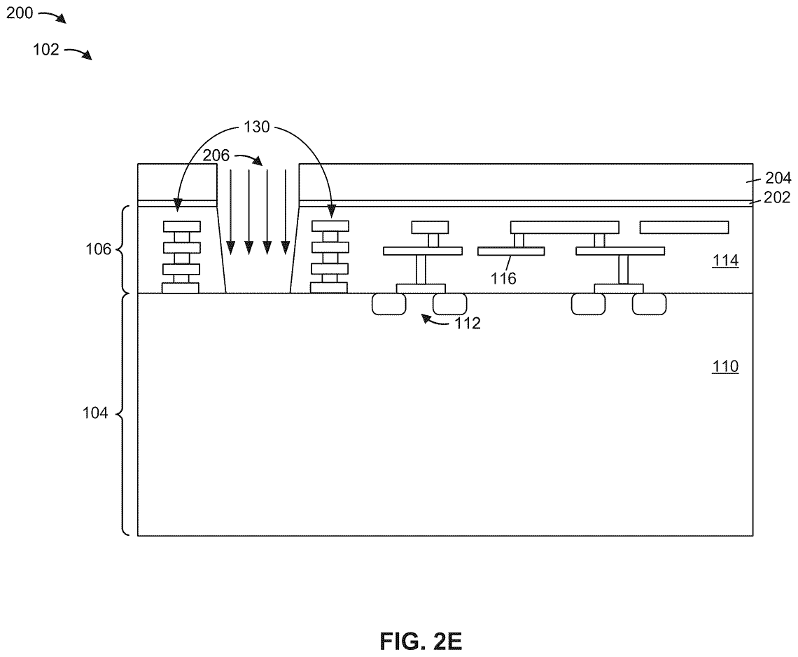

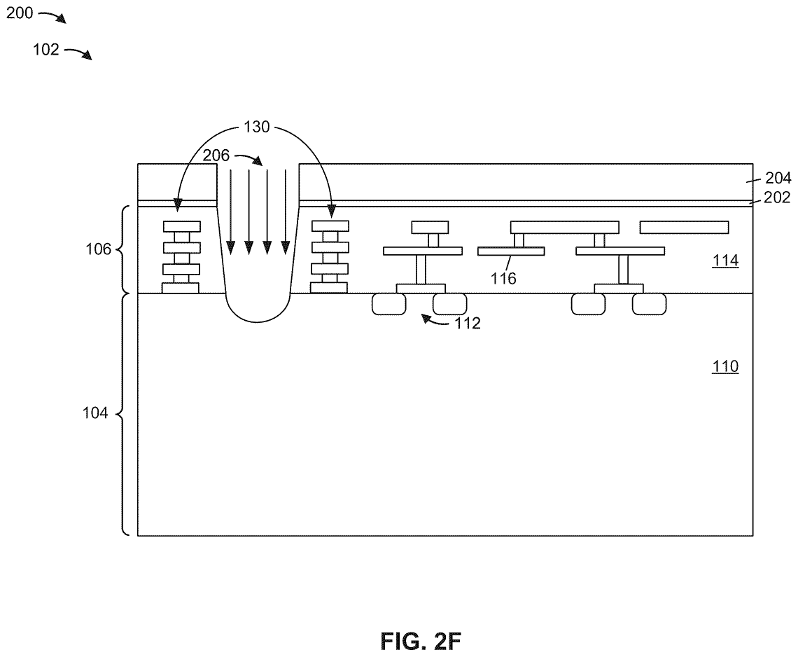

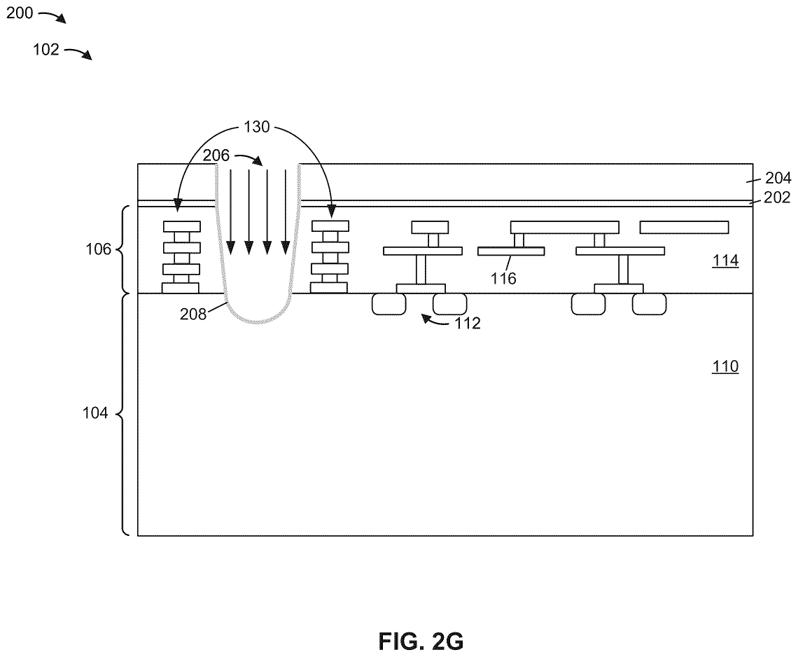

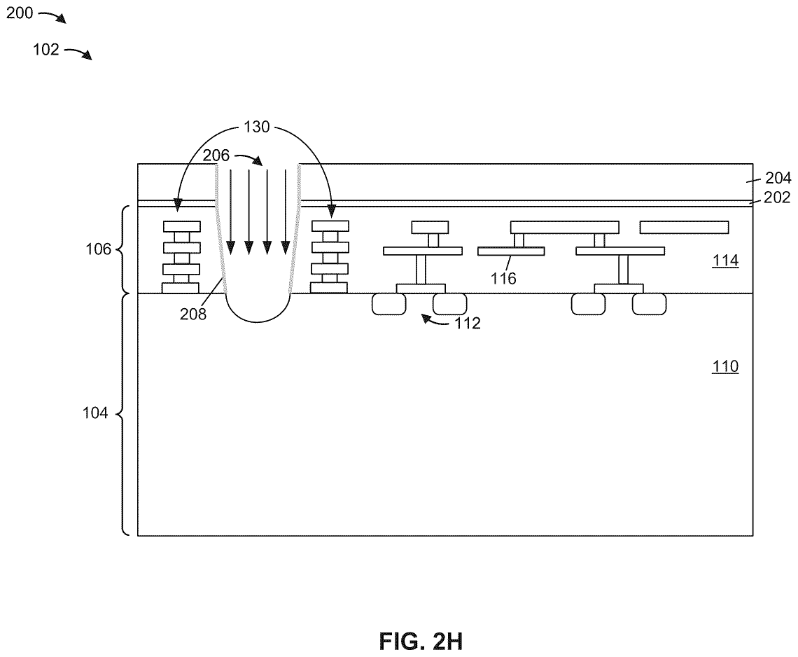

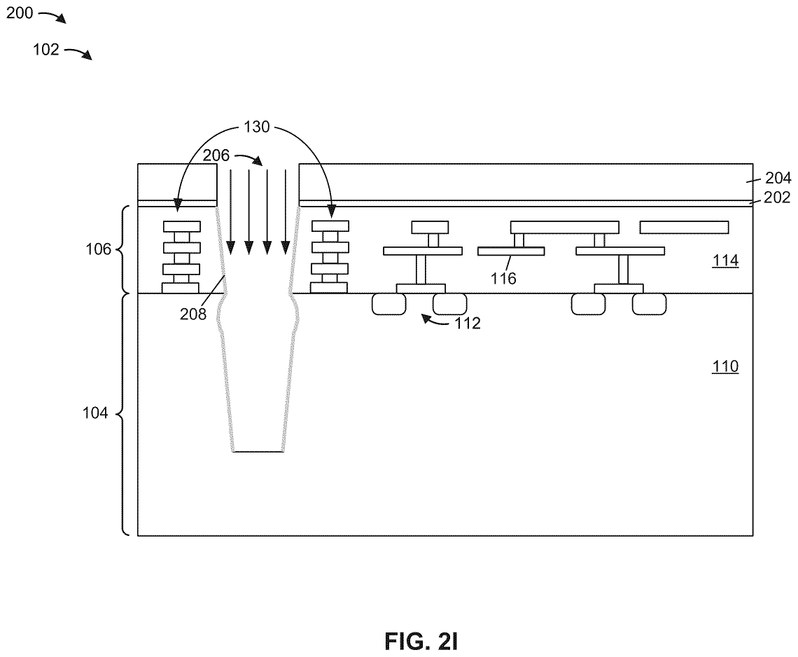

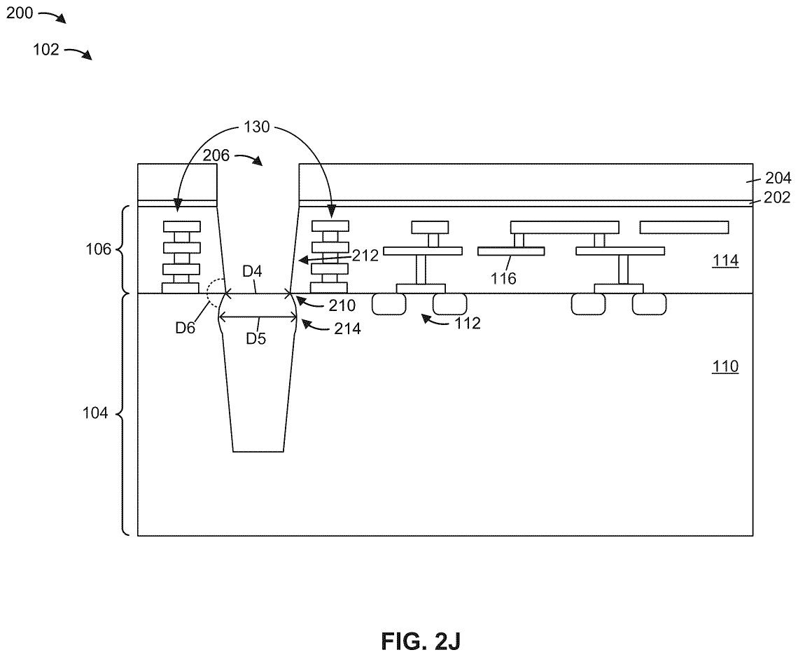

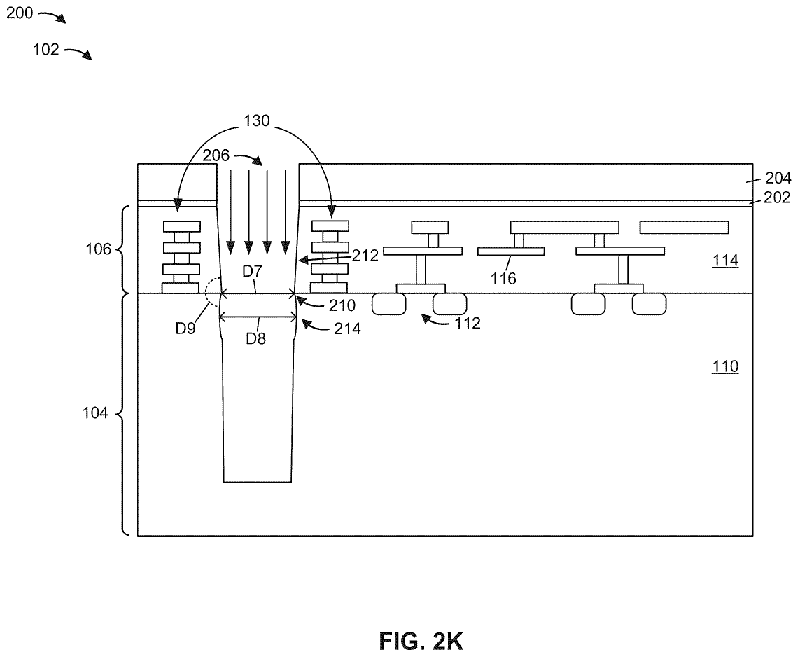

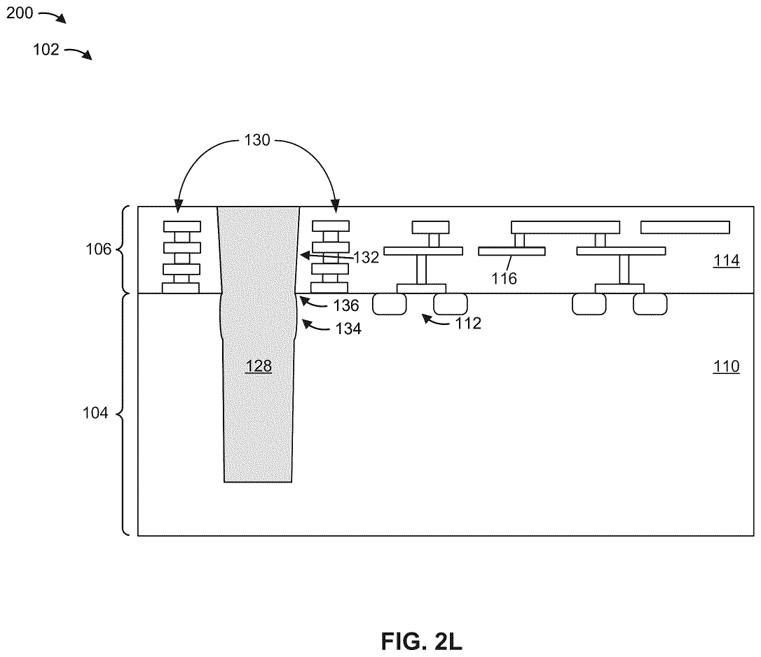

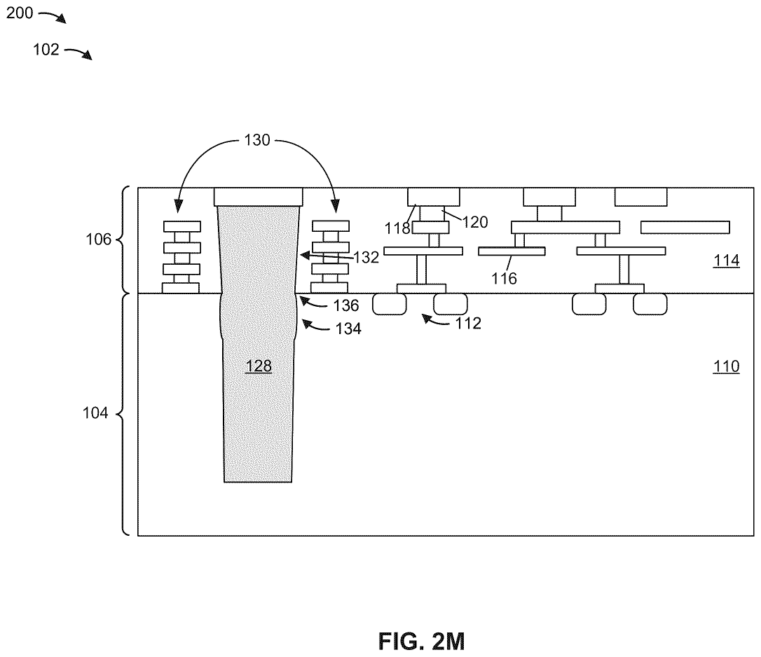

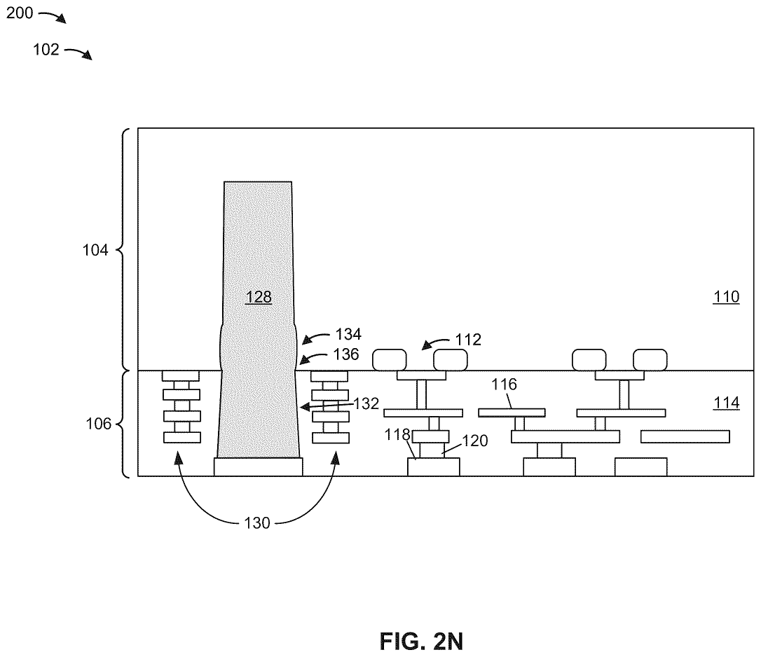

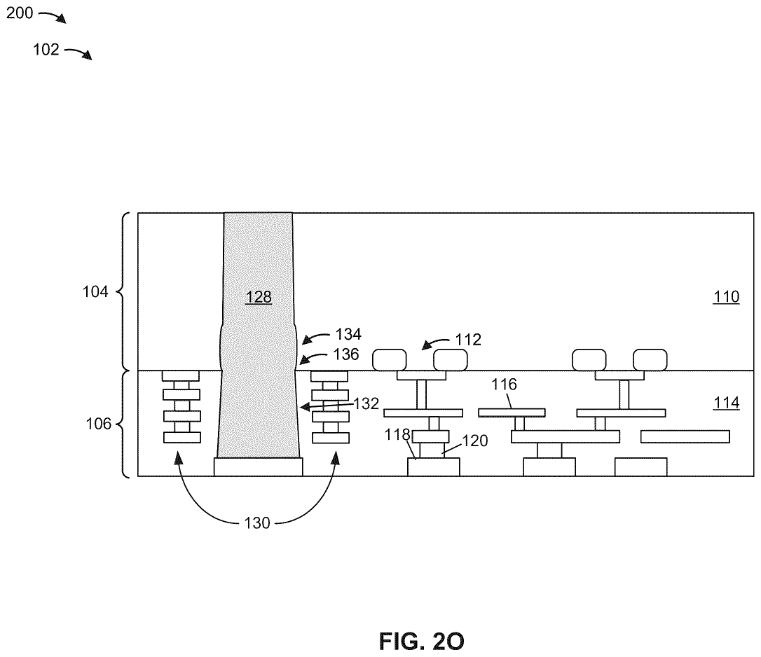

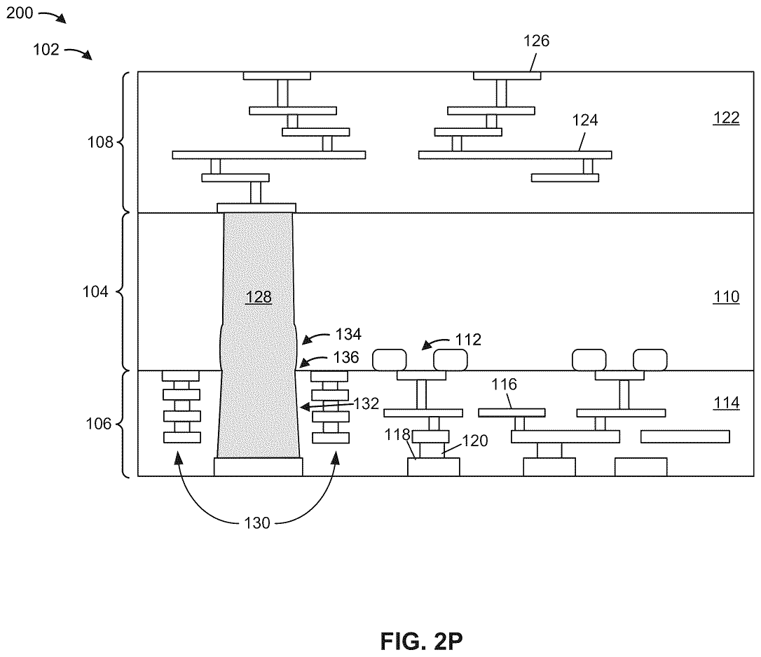

As described in greater detail in connection with FIGS. 2A-2P, a trimming operation may be performed during formation of the recess in which the through-substrate interconnect structure 128 is formed. The trimming operation may be performed to increase the outward sidewall angle of the transition between the sidewall profile of the tapered section 132 and the sidewall profile of the bowed section 134 (e.g., to reduce the severity or abruptness of the kink). In other words, the trimming operation results in the sidewalls of the recess being flatter through the transition between the sidewall profile of the tapered section 132 and the sidewall profile of the bowed section 134, which increases the gap-filling performance for depositing the material of the through-substrate interconnect structure 128 in the recess and reduces the likelihood of void formation at or near the transition 136. In some implementations, the outward sidewall angle (dimension D3) between the sidewall profile of the tapered section 132 and the sidewall profile of the bowed section 134 is included in a range of approximately 170 degrees to approximately 178 degrees, which may enable a low likelihood of void formation in the through-substrate interconnect structure 128 to be achieved. In some implementations, the outward sidewall angle may be up to approximately 180 degrees. However, other values and ranges are within the scope of the present disclosure.

The trimming operation may also reduce the difference between the lateral width of the through-substrate interconnect structure 128 at the transition 136 (dimension D1) and the lateral width of the through-substrate interconnect structure 128 at the approximate center height of the bowed section 134 (dimension D2). For example, the difference (e.g., D2-D1) may be greater than approximately 0.6 microns prior to the trimming operation, and may be approximately 0 microns to approximately 0.3 microns after the trimming operation. The lateral width of the through-substrate interconnect structure 128 at the transition 136 (dimension D1) and the lateral width of the through-substrate interconnect structure 128 at the approximate center height of the bowed section 134 (dimension D2) may each be included in a range of approximately 1.5 microns to approximately 6 microns. However, other values and ranges are within the scope of the present disclosure.

As indicated above, FIG. 1 is provided as an example. Other examples may differ from what is described with regard to FIG. 1.

FIGS. 2A-2P are diagrams of an example implementation 200 of forming the semiconductor device 102 described herein. FIGS. 2A-2M illustrate a frontside process for forming layers and/or structures in and/or above the frontside of the semiconductor device 102. FIGS. 2N-2P illustrate a backside process for forming layers and/or structures in and/or above the backside of the semiconductor device 102. In some implementations, one or more semiconductor processing tools may be used to perform one or more of the operations described in connection with the example implementation 200, such as a deposition tool, an exposure tool, a developer tool, an etch tool, a planarization tool, a plating tool, an ion implantation tool, an annealing tool, a bonding tool, and/or another type of semiconductor processing tool.

As shown in FIG. 2A, one or more of the operations in the example implementation 200 may be performed in connection with the semiconductor layer 110 of the semiconductor device 102. In some implementations, the semiconductor layer 110 may be provided in the form of a semiconductor wafer or another type of semiconductor substrate. In some implementations, a deposition tool is used to form or deposit the semiconductor layer 110 on a substrate by epitaxial growth.

As shown in FIG. 2B, the IC devices 112 of the device layer 104 may be formed in and/or on the semiconductor layer 110 of the semiconductor device 102. One or more semiconductor processing tools may be used to form one or more portions of the IC devices 112. For example, a deposition tool may be used to perform various deposition operations to deposit layers of the IC devices 112, and/or to deposit photoresist layers for etching the semiconductor layer 110 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer 110 and/or portions of the deposited layers to form the IC devices 112. As another example, a planarization tool may be used to planarize portions of the IC devices 112. As another example, an ion implantation tool may be used to implant ions in the semiconductor layer 110 to dope portions of the semiconductor layer 110 with one or more types of dopants (e.g., p-type dopants, n-type dopants).

As shown in FIG. 2C, the interconnect layer 106 (e.g., the frontside interconnect layer) may be formed above the frontside of the semiconductor layer 110 of the device layer 104. One or more semiconductor processing tools may be used to form the interconnect layer 106 by forming dielectric layers 114 and by forming one or more layers of conductive structures 116 in the dielectric layer(s) 114.

In some implementations, the interconnect layer 106 may be formed in a layer-by-layer process. For example, a first layer of the dielectric layer(s) 114 may be formed above the frontside of the semiconductor layer 110, recesses may be formed in the first layer, and a first layer of conductive structures 116 may be formed in the recesses. The first layer of conductive structures 116 may be electrically coupled and/or physically coupled to the IC devices 112 in the device layer 104. A second layer of the dielectric layer(s) 114 may be formed above the first layer, recesses may be formed in the second layer, and a second layer of conductive structures 116 may be formed in the recesses. Similar processing operations may be performed to form additional layers of the interconnect layer 106 until a sufficient or desired arrangement of conductive structures 116 is achieved. The layers of the guard ring structure 130 may also be formed as part of the layer-by-layer process.

A deposition tool may be used to deposit the material of the dielectric layer(s) 114 using a chemical vapor deposition (CVD) technique, an atomic layer deposition (ALD) technique, a physical vapor deposition (PVD) technique, and/or another suitable deposition technique. A planarization tool may be used to perform a planarization operation (e.g., a chemical-mechanical planarization (CMP) operation) to planarize the dielectric layer(s) 114.

An etch tool may be used to remove portions of a layer of the dielectric layer(s) 114 to form recesses therein. In some implementations, a pattern in a photoresist layer is used to etch the layer to form the recesses. In these implementations, a deposition tool may be used to form the photoresist layer on the layer of the dielectric layer(s) 114 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

A deposition tool may be used to deposit the material of the conductive structures 116 in the recesses using a CVD technique, an ALD technique, a PVD technique, an electroplating technique, and/or another type of deposition technique. In some implementations, a liner is formed in the recesses, and the material of the conductive structures 116 is deposited on the liner in the recesses. The liner may include a barrier liner, an adhesion liner, and/or another type of liner, and may include materials such as tantalum (Ta), tantalum nitride (TaN), silicon oxide (SiOₓ), silicon nitride (SiₓN_{y}), and/or titanium nitride (TiN), among other examples. In some implementations, a seed layer (e.g., a copper seed layer) is deposited in the recesses, and the material of the conductive structures 116 is deposited on the seed layer in the recesses.

As shown in FIG. 2D, a hard mask layer 202 may be formed over the interconnect layer 106, and a patterned masking layer 204 may be formed over the hard mask layer 202. The hard mask layer 202 may include a dielectric hard mask, a metal hard mask, and/or another type of hard mask layer. For example, the hard mask layer 202 may include silicon carbide (SiC), silicon oxynitride, silicon nitride (SiₓN_{y}), and/or another suitable hard mask material. The patterned masking layer 204 may include a photoresist layer that is patterned by photolithography.

A deposition tool may be used to deposit the material of the hard mask layer 202 using a PVD technique, an ALD technique, a CVD technique, an oxidation technique, and/or another suitable deposition technique. In some implementations, a planarization tool may be used to perform a planarization operation (e.g., a CMP operation) to planarize the hard mask layer 202 after the hard mask layer 202 is deposited.

A deposition tool may be used to deposit the material of the patterned masking layer 204 on the hard mask layer 202 using a spin-coating technique and/or another suitable deposition technique. An exposure tool may be used to expose the material of the patterned masking layer 204 to a radiation source to form a pattern therein. A developer tool may be used to develop and remove portions of the material to expose the pattern. The pattern may include an opening over a portion of the interconnect layer 106 located within an inner perimeter of the guard ring structure 130.

As shown in FIG. 2E, a first etch operation may be performed to etch the dielectric layer(s) 114 of the interconnect layer 106 to form a recess 206 that extend through the guard ring structure 130 in the interconnect layer 106. The first etch operation may stop once the semiconductor layer 110 is reached. Thus, the first etch operation may be performed to form the recess 206 to a first depth corresponding to a height of the interconnect layer 106. However, in some implementations, the recess 206 may extend slightly into the semiconductor layer 110.

An etch tool may be used to perform the first etch operation, which may include a dry etch operation or plasma-based etch operation. An etchant may be used that preferentially etches oxide materials, such as those included in the dielectric layer(s) 114 of the interconnect layer 106, with minimal etching of semiconductor materials of the semiconductor layer 110 such as a silicon (Si).

The dielectric layer(s) 114 of the interconnect layer 106 may be etched based on the pattern formed in the patterned masking layer 204 to form the recess 206. The pattern may be transferred to the hard mask layer 202 (e.g., by etching the hard mask layer 202 based on the pattern) and the combination of the patterned masking layer 204 and the hard mask layer 202 may be used to etch the dielectric layer(s) 114 to minimize the amount of taper in the sidewalls of the recess 206.

As shown in FIGS. 2F-2I, a cyclic etch process (sometimes referred to as a deep reactive ion etch (DRIE) or “BOSCH” etch) may be performed to extend the recess 206 to a second depth into the semiconductor layer 110 of the semiconductor device 102. The cyclic etch process may include a plurality of silicon etching operations using a plasma-based silicon etchant. The plasma-based silicon etchant may include a fluorine-containing plasma, such as an oxygen (O₂) plasma, a nitrogen (N₂) plasma, a carbon dioxide (CO₂) plasma, and/or another type of plasma that contains a fluorinated gas such as sulfur hexafluoride (SF₆).

As shown in FIG. 2F, a cycle of the cyclic etch process may include a first etch operation to etch into the semiconductor layer 110 using the plasma-based silicon etchant. Silicon may be removed from the semiconductor layer 110 by fluorine (F) radicals in the plasma-based silicon etchant. The plasma may split apart fluorine from the sulfur hexafluoride gas molecules in the plasma-based silicon etchant (e.g., SF₆→SF₄+2F or SF₆→SF₂+2F), and the fluorine radicals may react with silicon in the semiconductor layer 110 to create a silicon tetrafluoride gas byproduct (e.g., Si+4F→SiF₄).

As shown in FIG. 2G, the cycle of the cyclic etch process may include forming a protection layer 208 in and/or on the sidewalls and bottom surface of the recess 206. Forming the protection layer 208 may include providing a fluorocarbon gas such as a perfluorocyclobutane (e.g., C₄F₈) into the recess 206 such that the fluorocarbon gas reacts with the materials in the sidewalls and bottom surface of the recess 206 to form the protection layer 208.

As shown in FIG. 2H, the cycle of the cyclic etch process may include a trimming operation to trim the protection layer 208. The plasma-based silicon etchant may be used to etch through the protection layer 208 at the bottom of the recess 206 to expose the silicon material of the semiconductor layer 110 through the bottom of the recess 206. The protection layer 208 may be trimmed in an anisotropic manner by applying a radio frequency (RF) bias to control the directionality of the bombardment of ions in the plasma-based silicon etchant into the recess 206. The directionality promotes the bombardment of ions onto the bottom of the recess 206 while restricting bombardment of the ions onto the sidewalls of the recess 206.

As shown in FIG. 2I, the cycle of the cyclic etch process may include a second etch operation to etch the semiconductor layer 110 through the opening in the protection layer 208 at the bottom of the recess 206 to increase the depth of the recess 206 in the semiconductor layer 110. This may include the plasma-based silicon etchant (e.g., with or without the RF bias) to remove silicon material from the semiconductor layer 110.

In some implementations, forming the recess 206 may include a plurality of cycles described in connection with FIGS. 2F-2I. For example, 2 to 10 cycles may be performed to form the recess 206 to a particular depth in the semiconductor layer 110. However, other quantities and ranges are within the scope of the present disclosure.

In some implementations, after the cyclic etch process, a streamline etch may be performed to remove remaining material of the protection layer 208 on the sidewalls of the recess 206 and/or to clean the recess 206. An etch tool may be used to perform the streamline etch, which may include a plasma-based etch with a low plasma power and a low RF bias voltage applied to achieve a lower directionality and lower etch energy for omnidirectional cleaning in the streamline etch. For example, the plasma power for the etch tool may be included in a range of approximately 500 watts to approximately 3000 watts for the streamline etch, and the RF bias voltage applied by the etch tool may be included in a range of approximately 0 volts to approximately 300 volts for the streamline etch. However, other values and ranges are within the scope of the present disclosure.

Plasmas such as an oxygen (O₂) plasma, a nitrogen (N₂) plasma, a carbon dioxide (CO₂) plasma, and/or another type of plasma may be used in the streamline etch. A pressure in the processing chamber of the etch tool for the streamline etch may be included in a range of approximately 5 millitorr to approximately 100 millitorr. However, other values and ranges are within the scope of the present disclosure. The streamline etch may be performed for a duration of approximately 20 seconds to approximately 30 seconds. However, other values and ranges are within the scope of the present disclosure.

As shown in FIG. 2J, after the streamline etch, the recess 206 may have a sidewall profile that contains a transition 210 between a tapered section 212 in the interconnect layer 106 and a bowed section 214 in the semiconductor layer 110. The difference between a lateral width (indicated in FIG. 2J as a dimension D4) of the recess 206 at the transition 210 and a lateral width (indicated in FIG. 2J as a dimension D5) of the recess 206 in the bowed section 214 (e.g., D5-D4) may be greater than approximately 0.6 microns. Moreover, an outward sidewall angle (indicated in FIG. 2J as a dimension D6) between the sidewall profile of the tapered section 212 and the sidewall profile of the bowed section 214 may be less than approximately 140 degrees. However, other values and ranges are within the scope of the present disclosure.

As shown in FIG. 2K, a trimming operation may be performed (e.g., after the streamline etch) to reduce the difference between the lateral width of the recess 206 at the transition 210 and the lateral width of the recess 206 in the bowed section 214, and/or to increase the outward sidewall angle between the sidewall profile of the tapered section 212 and the sidewall profile of the bowed section 214. In other words, the trimming operation may be performed to flatten the sidewalls of the recess 206 by lessening or removing a kink at the transition 210.

An etch tool may be used to perform the trimming operation, which may include a plasma-based etch using a plasma and one or more process gases. The plasma-based etchant may include an oxygen (O₂) plasma, a nitrogen (N₂) plasma, a carbon dioxide (CO₂) plasma, a helium (He) plasma, and/or another type of plasma.

In some implementations, the trimming operation may be performed “in-situ” in the processing chamber of the etch tool along with the streamline etch described in connection with FIG. 2J. This may include performing the streamline etch, followed by the trimming operation, without breaking a vacuum in the processing chamber of the etch tool. For example, the streamline etch may be performed using a plasma-based etchant, and then additional process gases may be introduced into the plasma in the processing chamber (e.g., without breaking the vacuum in the processing chamber) to transition to the trimming operation.

Additional parameters may be altered from the streamline etch for the trimming operation, such as increasing the plasma power for the trimming operation relative to the streamline etch and/or increasing the RF bias voltage for the trimming operation relative to the streamline etch. The increased plasma power may result in a greater amount of ions being generated (e.g., for a more aggressive etch), and the increased RF bias voltage may result in greater directionality (e.g., for a more vertical etch) for the trimming operation. The combination of these parameters, in combination with the additional process gases, may enable the profile of the sidewalls of the recess 206 to be smoothed, particularly at the transition 210 between the tapered section 212 and the bowed section 214 of the recess 206.

The additional process gases may be introduced into the processing chamber to alter the etch rate of the plasma-based etchant for the dielectric material of the dielectric layer(s) 114 of the interconnect layer 106. In particular, the process gases may increase the etch rate of the plasma-based etchant for the dielectric material of the dielectric layer(s) 114 of the interconnect layer 106 relative to the etch rate in the streamline etch. The additional process gases may include one or more fluorocarbon gases, such as a tetrafluoromethane (CF₄) gas, an octafluorocyclobutane (C₄F₈) gas, and/or a sulfur hexafluoride (SF₆) gas, among other examples.

The increased etch rate in the interconnect layer 106 provided by the additional process gases, alone or in addition to the increased plasma power and/or the increased RF vias voltage, results in directional (e.g., vertical) etching of the dielectric layer(s) 114 at the bottom of interconnect layer 106 near the transition 210, which widens the recess 206 at the transition and increases the verticality (e.g., reduced the taper) of the sidewalls in the tapered section 212. Etching of the sidewalls of the recess 206 in the bowed section 214 may also occur, which may flatten out the sidewalls of the recess 206 in the bowed section 214.

In some implementations, the plasma power for the trimming operation may be included in a range of approximately 1000 watts to approximately 3000 watts to achieve sufficient ion generation while minimizing over-etching into the semiconductor layer 110. However, other values and ranges are within the scope of the present disclosure. In some implementations, the RF bias voltage for the trimming operation may be included in a range of approximately 200 volts to approximately 800 watts to achieve sufficient directionality (e.g., verticality) in the etch direction in the trimming operation. However, other values and ranges are within the scope of the present disclosure. In some implementations, a pressure in the processing chamber of the etch tool for the trimming operation may be included in a range of approximately 5 millitorr to approximately 100 millitorr. However, other values and ranges are within the scope of the present disclosure. In some implementations, the trimming operation may be performed for a duration of approximately 50 seconds to approximately 60 seconds. However, other values and ranges are within the scope of the present disclosure.

As further shown in FIG. 2K, the difference between a lateral width (indicated in FIG. 2K as a dimension D7) of the recess 206 at the transition 210 and a lateral width (indicated in FIG. 2K as a dimension D8) of the recess 206 in the bowed section 214 after the trimming operation (e.g., D8-D7) may be less than 0.6 microns, and may be included in a range of approximately 0 microns to approximately 0.3 microns. However, other values and ranges are within the scope of the present disclosure. In some implementations, a ratio of the lateral width of the recess 206 at the transition 210 to a lateral width of the recess 206 in the bowed section 214 after the trimming operation (e.g., D7:D8) may be included in a range of approximately 0.86:1 to approximately 0.99:1. However, other values and ranges are within the scope of the present disclosure.

The lateral width of the recess 206 at the transition 210 after the trimming operation (dimension D7) may be greater than the lateral width of the recess 206 at the transition 210 prior to the trimming operation (dimension D4). In some implementations, a ratio of the lateral width of the recess 206 at the transition 210 after the trimming operation to the lateral width of the recess 206 at the transition 210 prior to the trimming operation (D7:D4) may be greater than 1:1 and up to approximately 1.2:1. However, other values and ranges are within the scope of the present disclosure.

The lateral width of the recess 206 in the bowed section 214 after the trimming operation (dimension D8) and the lateral width of the recess 206 in the bowed section 214 prior to the trimming operation (dimension D5) may be approximately equal. In some implementations, a ratio of the lateral width of the recess 206 in the bowed section 214 after the trimming operation to the lateral width of the recess 206 in the bowed section 214 prior to the trimming operation (D8:D5) may be approximately 1:1. However, other values and ranges are within the scope of the present disclosure.

Moreover, the outward sidewall angle (indicated in FIG. 2K as a dimension D9) between the sidewall profile of the tapered section 212 and the sidewall profile of the bowed section 214 may be greater than approximately 140 degrees after the trimming operation, and may be included in a range of approximately 170 degrees to approximately 178 degrees or greater. However, other values and ranges are within the scope of the present disclosure.

As shown in FIG. 2L, material of a through-substrate interconnect structure 128 may be deposited in the recess 206. A deposition tool may be used to deposit the material of the through-substrate interconnect structure 128 using a CVD technique, an ALD technique, a PVD technique, an electroplating technique, and/or another suitable deposition technique. A planarization tool may be used to perform a planarization operation (e.g., a CMP operation) to planarize the through-substrate interconnect structure 128 such that the top of the through-substrate interconnect structure 128 is approximately co-planar with the top of the interconnect layer 106. The flattened sidewalls of the recess 206, achieved by the trimming operation described in connection with FIG. 2K, increases the gap-filling performance for depositing the material of the through-substrate interconnect structure 128 in the recess 206, which reduces the likelihood of void formation at or near the transition 136 between the tapered section 132 and the bowed section 134 of the through-substrate interconnect structure 128.

As shown in FIG. 2M, additional dielectric layer(s) 114 of the interconnect layer 106 may be formed above the through-substrate interconnect structure 128, and the bonding vias 120 and the bonding pads 118 may be formed in the additional dielectric layer(s) 114. For example, a deposition tool may be used to deposit the additional dielectric layer(s) 114 using a CVD technique, a PVD technique, an ALD technique, an oxidation technique, and/or another suitable deposition technique. An etch tool may be used to etch the additional dielectric layer(s) 114 to form recesses in the additional dielectric layer(s) 114. A deposition tool may be used to deposit the material of the bonding vias 120 and the bonding pads 118 in the recesses using a CVD technique, a PVD technique, an ALD technique, an electroplating technique, and/or another suitable deposition technique. One or more of the bonding vias 120 and/or one or more of the bonding pads 118 may be formed on the through-substrate interconnect structure 128.

As shown in FIG. 2N, the semiconductor device 102 may be flipped in a vertical direction such that the backside of the semiconductor layer 110 is facing upward. The interconnect layer 106 may be bonded to a carrier substrate to facilitate backside processing of the semiconductor device 102.

As shown in FIG. 20, a wafer grinding operation may be performed on the backside of the semiconductor layer 110 to reduce the thickness of the semiconductor layer 110. A grinding tool may be used to remove material from the semiconductor layer 110 by wafer grinding. The grinding operation may be stopped after the bottom of the through-substrate interconnect structure 128 is exposed through the backside of the semiconductor layer 110.

As shown in FIG. 2P, the interconnect layer 108 (e.g., the backside interconnect layer) may be formed over the backside of the semiconductor layer 110. The dielectric layer(s) 122 and the conductive structures 124 of the interconnect layer 108 may be formed in a similar manner as described in connection with FIG. 2C for the interconnect layer 106. In some implementations, one or more of the conductive structures 124 may be formed on the exposed end of the through-substrate interconnect structure 128 so that the conductive structures 124 of the interconnect layer 108 are connected to the conductive structures 116 of the interconnect layer 106 through the through-substrate interconnect structure 128.

As indicated above, FIGS. 2A-2P are provided as an example. Other examples may differ from what is described with regard to FIGS. 2A-2P.

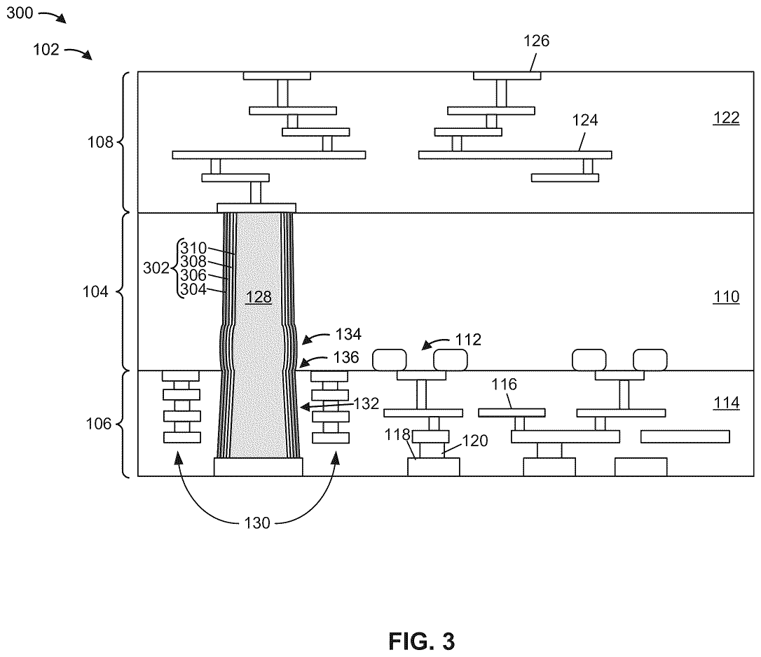

FIG. 3 is a diagram of an example implementation 300 of the semiconductor device 102 described herein. As shown in FIG. 3, the example implementation 300 of the semiconductor device 102 is similar to the example implementation 100 of the semiconductor device 102 illustrated in FIG. 1. However, in the example implementation 300, the semiconductor device 102 includes one or more liners 302 on the sidewalls of a through-substrate interconnect structure 128.

The liners 302 may include a liner 304, a liner 306, a liner 308, and/or a liner 310, among other examples. The liners 302 may be included as adhesion liners (e.g., to promote adhesion of the through-substrate interconnect structure 128 to the surrounding layers), barrier liners (e.g., to inhibit diffusion of material from the through-substrate interconnect structure 128 into the surrounding layers), and/or another type of liners. In some implementations, the liner 304 may include an oxide liner (e.g., a silicon oxide (SiOₓ) liner), the liner 306 may include a titanium (Ti) liner, the liner 308 may include a titanium nitride (TiN) liner, and/or the liner 310 may include another titanium liner. In some implementations, a different quantity of liners 302 are included along the sidewalls of the through-substrate interconnect structure 128. In some implementations, a different combination of materials for the liners 302 is included along the sidewalls of the through-substrate interconnect structure 128.

As indicated above, FIG. 3 is provided as an example. Other examples may differ from what is described with regard to FIG. 3.

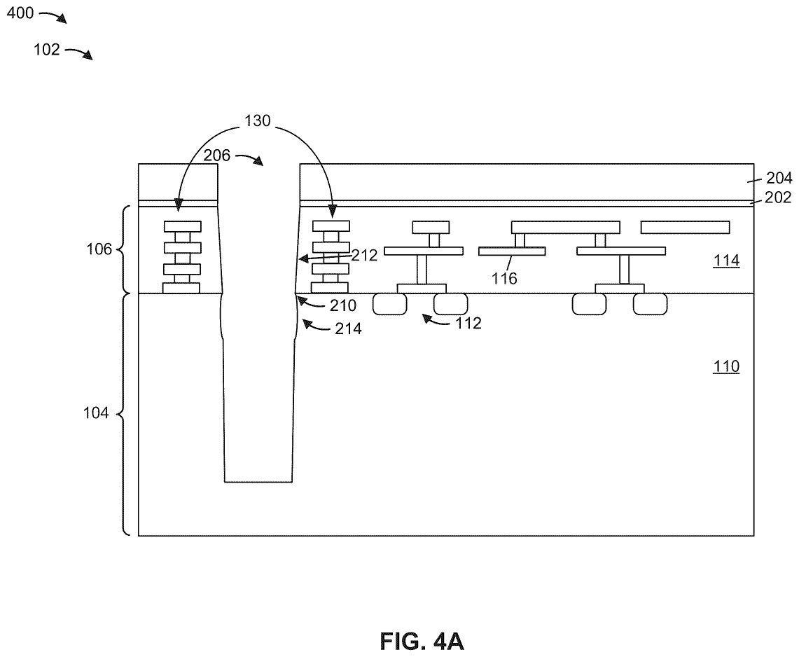

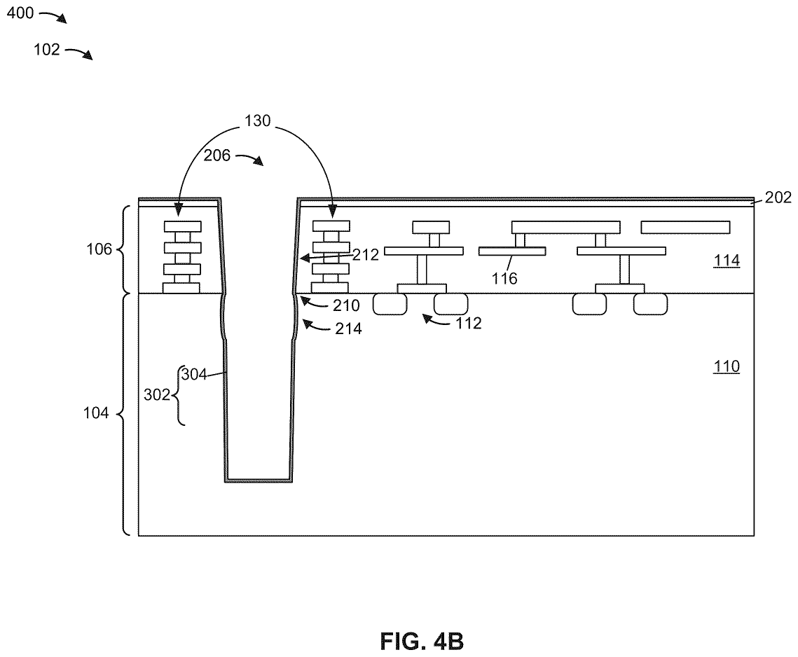

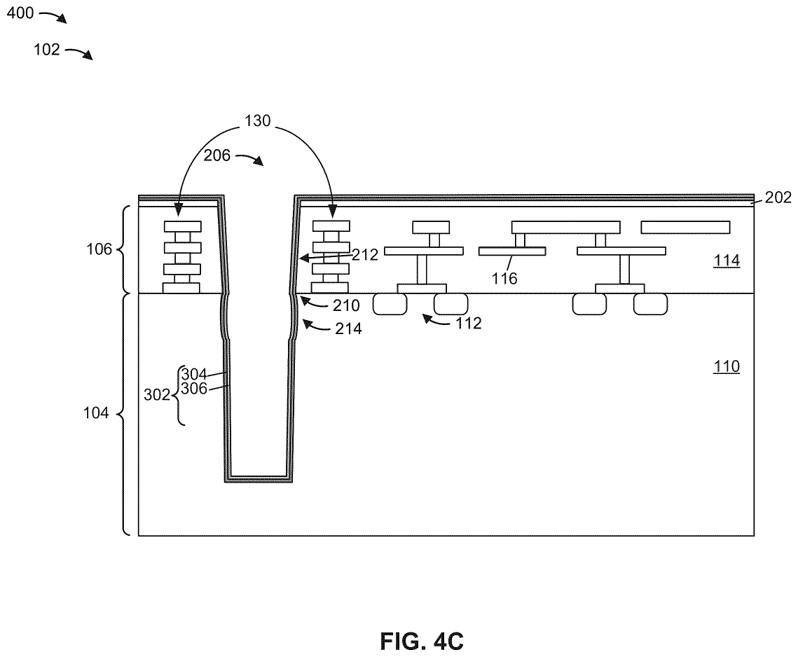

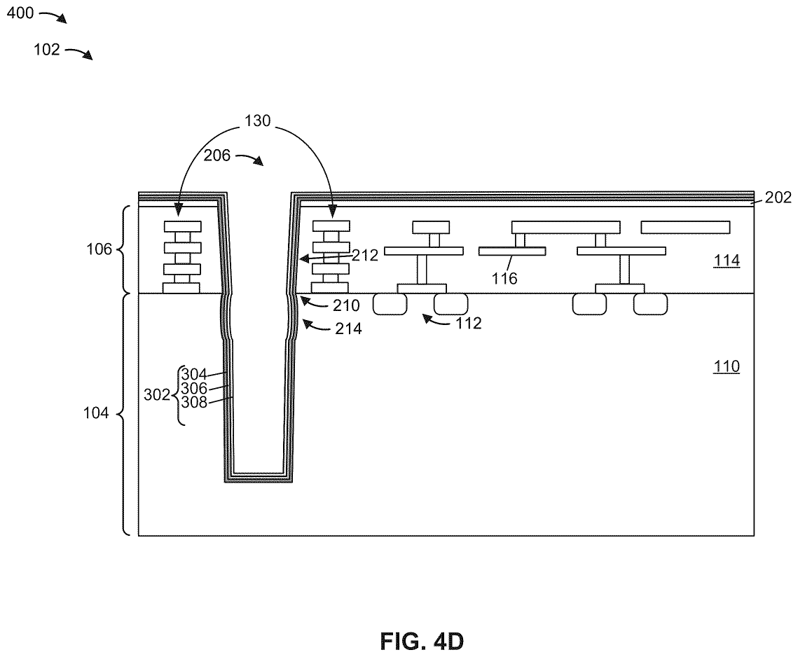

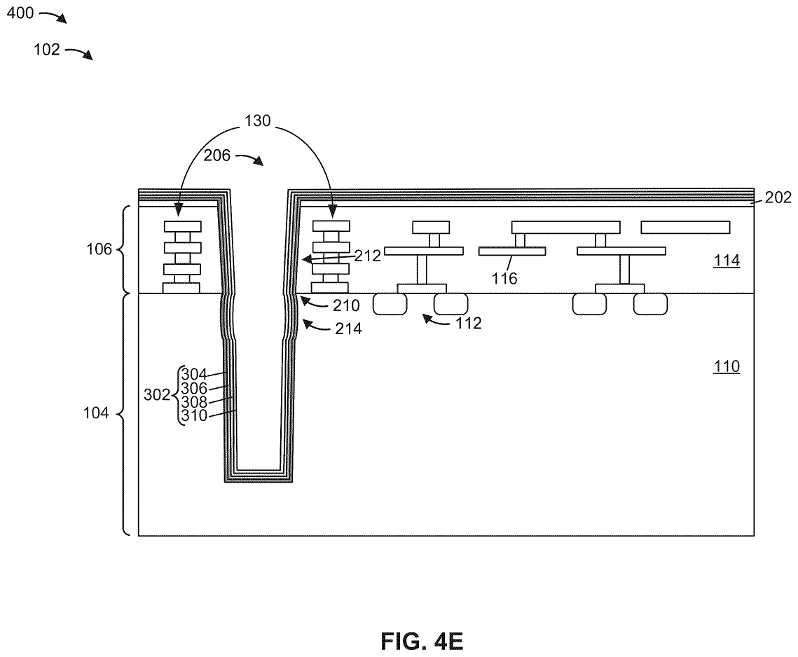

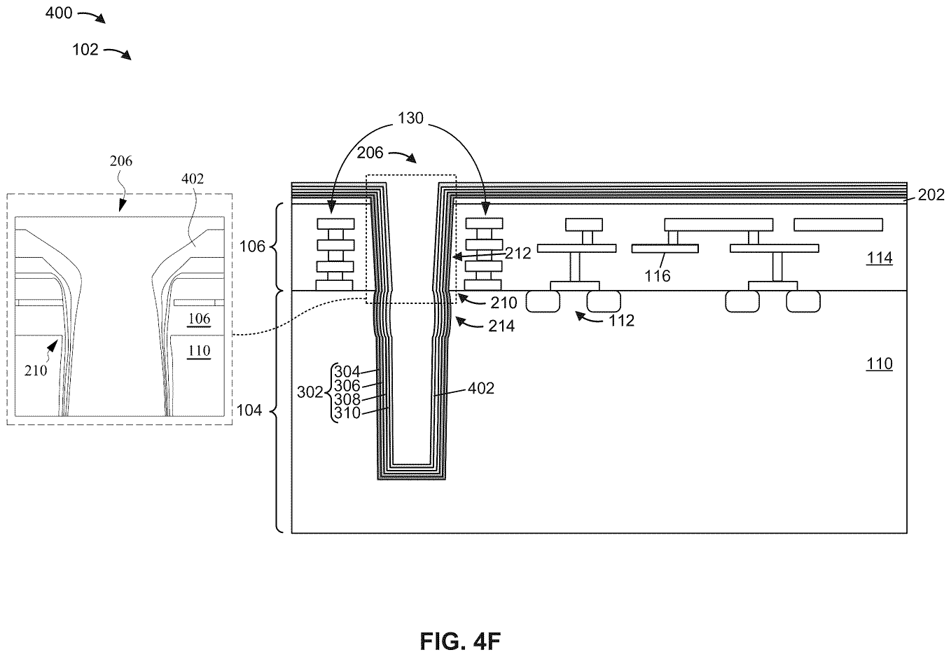

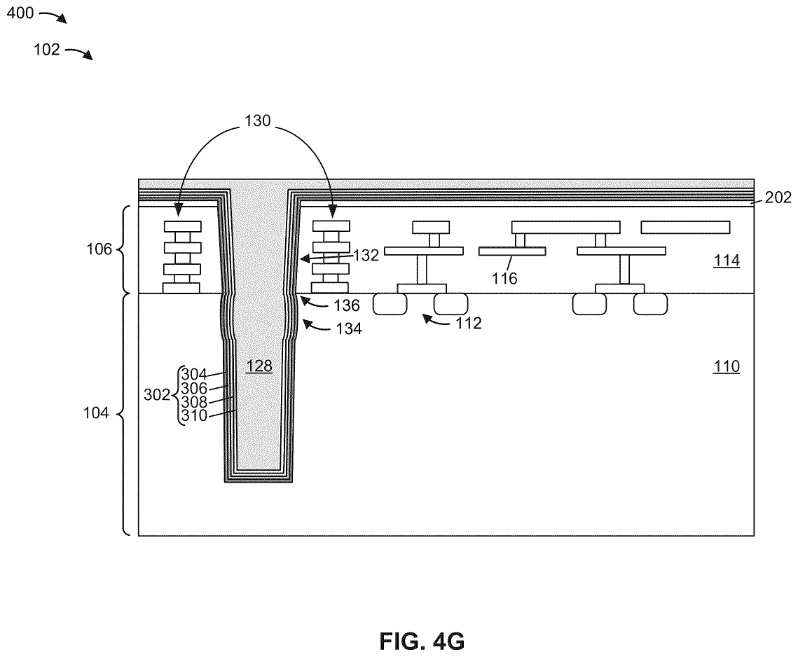

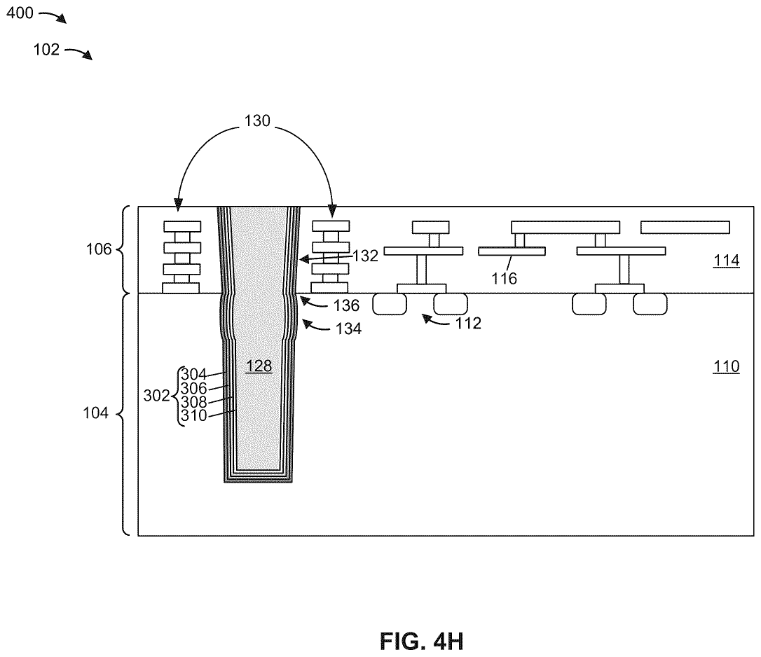

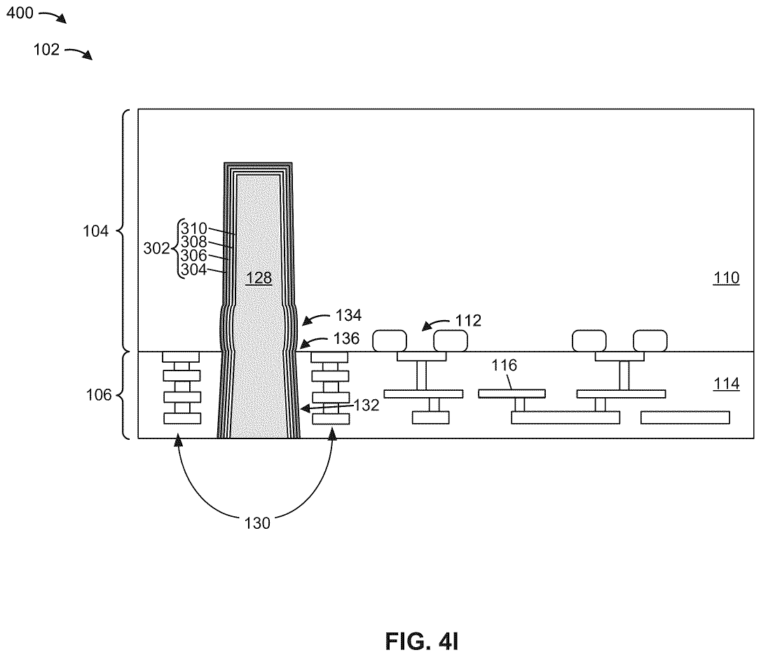

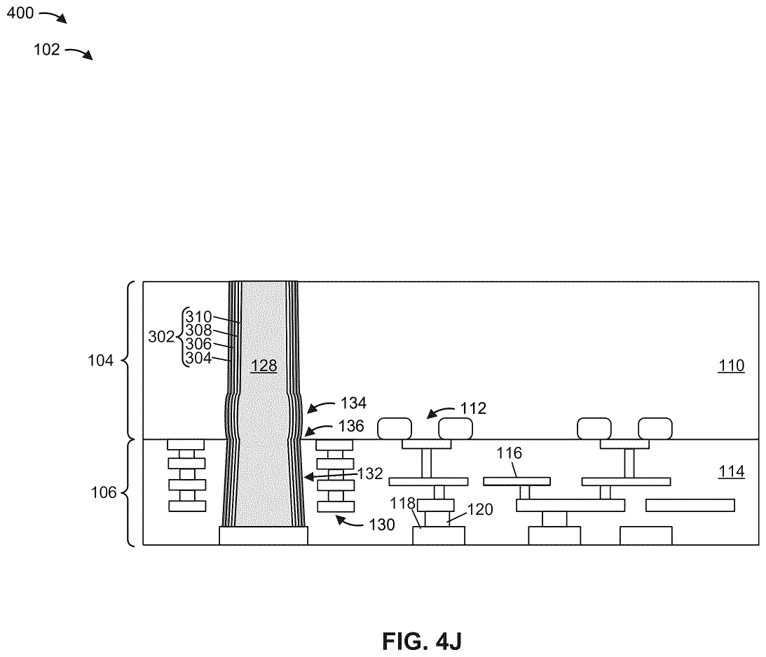

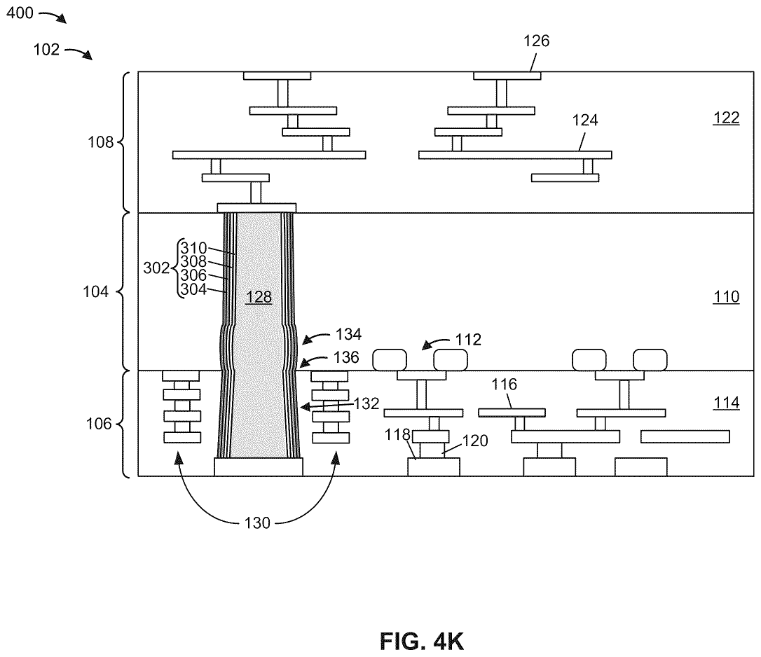

FIGS. 4A-4K are diagrams of an example implementation 400 of forming the semiconductor device 102 described herein. In particular, the example implementation 400 includes an example of forming the liners 302 for the through-substrate interconnect structure 128 in the example implementation 300 of the semiconductor device 102. In some implementations, one or more semiconductor processing tools may be used to perform one or more of the operations described in connection with the example implementation 400, such as a deposition tool, an exposure tool, a developer tool, an etch tool, a planarization tool, a plating tool, an ion implantation tool, an annealing tool, a bonding tool, and/or another type of semiconductor processing tool.

As shown in FIG. 4A, similar operations as illustrated and described in connection with FIGS. 2A-2K may be performed to form the recess 206 through the interconnect layer 106 and into the semiconductor layer 110.

As shown in FIGS. 4B-4E, the liners 302 may be deposited along the sidewalls and the bottom surface of the recess 206. The liners 302 may also extend along the top surface of the hard mask layer 202. As shown in FIG. 4B, a deposition tool may be used to deposit the material of the liner 304 on the sidewalls and the bottom surface of the recess 206 using a CVD technique, an ALD technique, a PVD technique, and/or another suitable technique. As shown in FIG. 4C, a deposition tool may be used to deposit the material of the liner 306 over the liner 304 on the sidewalls and the bottom surface of the recess 206 using a CVD technique, an ALD technique, a PVD technique, and/or another suitable technique. As shown in FIG. 4D, a deposition tool may be used to deposit the material of the liner 308 over liner 306 on the sidewalls and the bottom surface of the recess 206 using a CVD technique, an ALD technique, a PVD technique, and/or another suitable technique. As shown in FIG. 4E, a deposition tool may be used to deposit the material of the liner 310 over the liner 308 on the sidewalls and the bottom surface of the recess 206 using a CVD technique, an ALD technique, a PVD technique, and/or another suitable technique.

As shown in FIG. 4F, a seed layer 402 may be deposited on the sidewalls and the bottom surface of the recess 206. The seed layer 402 may include a layer of the same material that is to be deposited for the through-substrate interconnect structure 128. For example, if the through-substrate interconnect structure 128 is to be formed of copper (Cu), the seed layer 402 may include a layer of copper (Cu). The seed layer 402 may be deposited in the recess 206 as a base layer on which the material of the through-substrate interconnect structure 128 is to be deposited to promote uniform adhesion and growth of the material of the through-substrate interconnect structure 128.

The seed layer 402 may be a thin layer of material (e.g., on the order of nanometers) and may be deposited using a CVD technique, an ALD technique, a PVD technique, and/or another suitable technique. Because the seed layer 402 is a thin film of material, the seed layer 402 may be susceptible to formation of discontinuities in the seed layer 402, particularly in areas of the recess 206 that have sharp outside corners or abrupt transitions. Discontinuities in the seed layer 402 might otherwise result in degraded growth uniformity of the through-substrate interconnect structure 128, which in turn may lead to the formation of discontinuities in the through-substrate interconnect structure 128.

The operations described in connection with FIGS. 2E-2K, such as the trimming operation described in connection with FIG. 2K, flatten the sidewalls of the recess 206 by lessening or removing a kink at the transition 210. The flatter overall profile of the sidewalls of the recess 206 increases film deposition performance for depositing the material of the seed layer 402 in the recess 206, which reduces the likelihood of formation of discontinuities in the seed layer 402 along the sidewalls of the recess 206. As shown in a close-up view in FIG. 4F, the resulting seed layer 402 may be continuous through the transition 210 between the tapered section 212 and the bowed section 214.

As shown in FIG. 4G, the material of the through-substrate interconnect structure 128 may be deposited on the seed layer 402 in the recess 206. Excess material of the through-substrate interconnect structure 128 may be deposited along the hard mask layer 202.

Accordingly, and as shown in FIG. 4H, a planarization tool may be used to perform a planarization operation (e.g., a CMP operation) to remove the excess material of the through-substrate interconnect structure 128, the excess material of the liners 302, and the hard mask layer 202 from the interconnect layer 106.

As shown in FIG. 4I, the semiconductor device 102 may be flipped for backside processing. As shown in FIG. 4J, a wafer grinding operation may be performed on the backside of the semiconductor layer 110 to reduce the thickness of the semiconductor layer 110. A grinding tool may be used to remove material from the semiconductor layer 110 by wafer grinding. The grinding operation may be stopped after the bottom of the through-substrate interconnect structure 128 is exposed through the backside of the semiconductor layer 110. Thus, the portions of the liners 302 on the bottom of the through-substrate interconnect structure 128 may be removed, leaving behind portions of the liners 302 on the sidewalls of the through-substrate interconnect structure 128. Removal of the liners 302 from the bottom of the through-substrate interconnect structure 128 enables a conductive structure 124 of the interconnect layer 108 to be formed on the bottom of the through-substrate interconnect structure 128, as shown in FIG. 4K, which enables a low contact resistance to be achieved between the conductive structure 124 and the through-substrate interconnect structure 128.

As indicated above, FIGS. 4A-4K are provided as an example. Other examples may differ from what is described with regard to FIGS. 4A-4K.

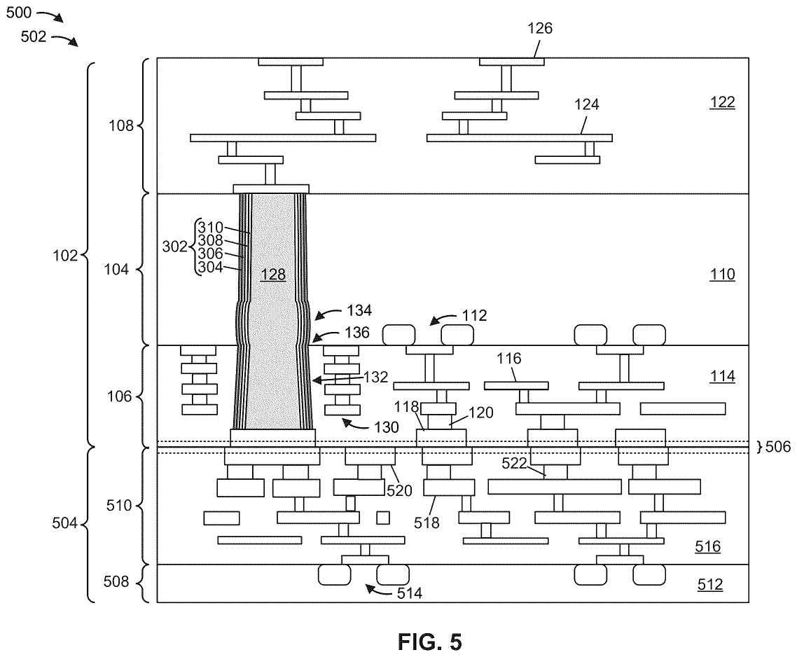

FIG. 5 is a diagram of an example implementation 500 of the semiconductor package 502 described herein. As shown in FIG. 5, the semiconductor package 502 includes the semiconductor device 102 and a semiconductor device 504 bonded at a bonding interface 506 such that the semiconductor devices 102 and 504 are stacked and vertically arranged (e.g., in a z-direction) in the semiconductor package 502. The semiconductor package 502 may be referred to as an IC die package or system on integrated chip (SoIC), and the semiconductor devices 102 and 504 may correspond to the IC dies or IC layers of the IC die package or SoIC.

The bond between the semiconductor devices 102 and 504 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor devices 102 and 504 by forming metal-to-metal bonds and/or dielectric-to-dielectric bonds at the bonding interface 506 between the semiconductor devices 102 and 504.

The semiconductor device 504 may include an SoC die, such as a logic die, a CPU die, a GPU die, a DSP die, an ASIC die, and/or another type of SoC die. Additionally and/or alternatively, the semiconductor device 504 may include a memory die, an I/O die, a pixel sensor die, a co-packaged optics die, and/or another type of IC die. The semiconductor device 504 may include the same type of semiconductor device as the semiconductor device 102, or may include a different type of semiconductor device.

In some implementations, the semiconductor package 502 is an SoC package, and the semiconductor devices 102 and 504 are functional layers of the SoC package. For example, the semiconductor device 102 may correspond to an I/O layer of the SoC package, and the semiconductor device 504 may correspond to the logic layer of the SoC package. In some implementations, the semiconductor package 502 is an HBM package, and the semiconductor devices 102 and 504 each correspond to a memory layer or HBM layer of the HBM package.

As further shown in FIG. 5, the semiconductor device 504 may include a device layer 508 and an interconnect layer 510 adjacent to a side (e.g., vertically adjacent to a frontside) of the device layer 508. The device layer 508 may include a semiconductor layer 512 and one or more IC devices 514 in and/or on the semiconductor layer 512. The interconnect layer 510 may include one or more dielectric layers 516, one or more layers of conductive structures 518 in the one or more dielectric layers 516, bonding pads 520, and bonding vias 522 that couple the bonding pads 520 to the conductive structure 518.

At the bonding interface 506, the bonding pads 118 of the semiconductor device 102 and the bonding pads 520 of the semiconductor device 504 are directly bonded by metal-to-metal bonds. Moreover, a dielectric layer 114 of the semiconductor device 102 and a dielectric layer 516 of the semiconductor device 504 are directly bonded by dielectric-to-dielectric bonds.

A bonding pad 118 coupled to the through-substrate interconnect structure 128 of the semiconductor device 102 may be bonded to a bonding pad 520 of the semiconductor device 504. The bonding pads 118, the conductive structures 124, the through-substrate interconnect structure 128, conductive structures 518, the bonding pads 520, and the bonding vias 522 provide a signal and and/or power propagation path between the IC devices 514 of the semiconductor device 504 and the interconnect layer 108 of the semiconductor device 102.

As indicated above, FIG. 5 is provided as an example. Other examples may differ from what is described with regard to FIG. 5.

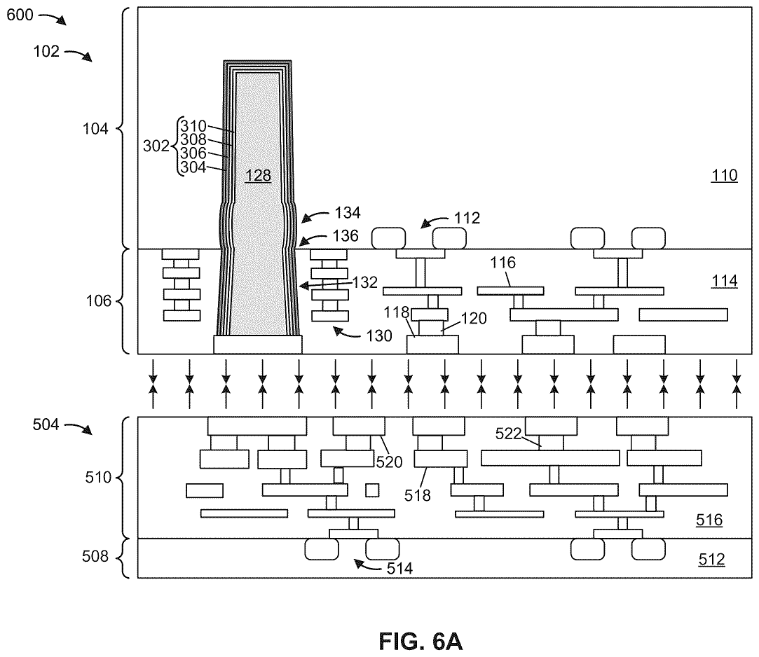

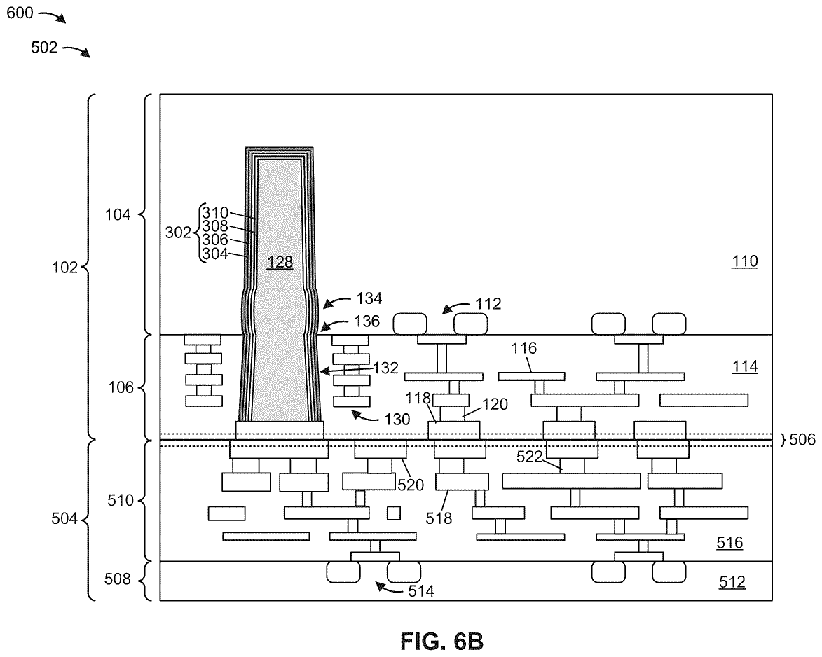

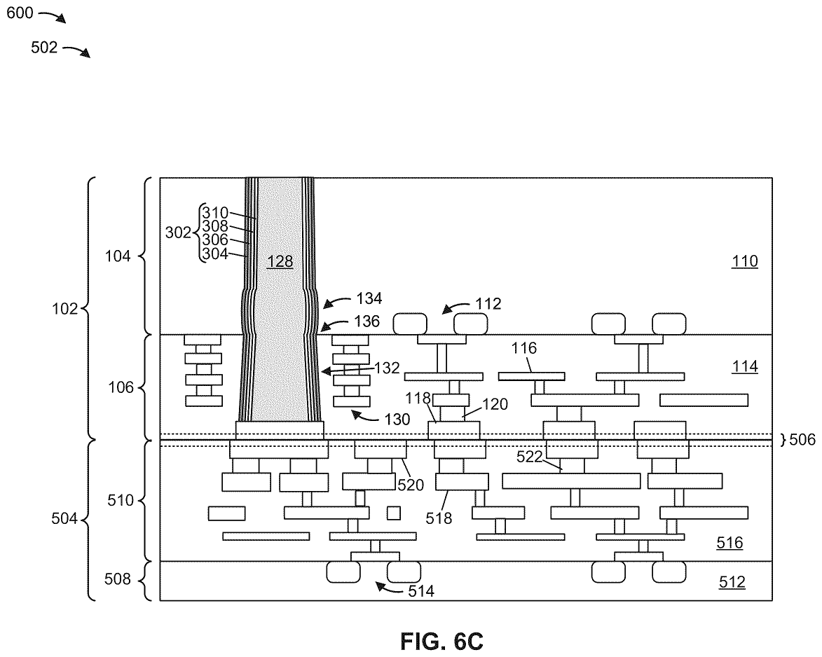

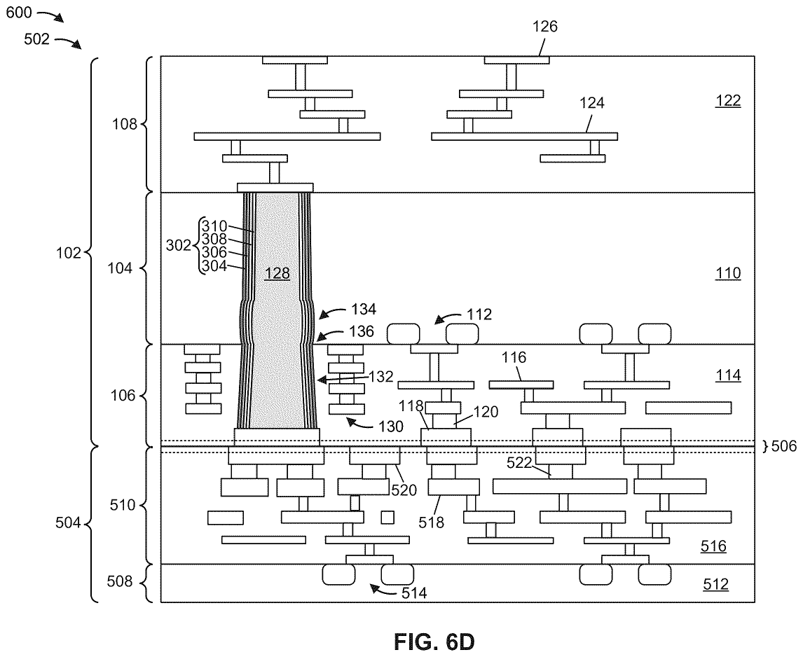

FIGS. 6A-6D are diagrams of an example implementation 600 of forming the semiconductor package 502 described herein. In some implementations, one or more semiconductor processing tools may be used to perform one or more of the operations described in connection with the example implementation 500, such as a deposition tool, an exposure tool, a developer tool, an etch tool, a planarization tool, a plating tool, an ion implantation tool, an annealing tool, a bonding tool, and/or another type of semiconductor processing tool.

As shown in FIGS. 6A and 6B, a bonding operation is performed to bond the semiconductor devices 102 and 504 at the bonding interface 506 such that the semiconductor devices 102 and 504 are vertically arranged or stacked (e.g., in the z-direction) in the semiconductor package 502. The semiconductor devices 102 and 504 may be vertically arranged or stacked in a wafer-on-wafer (WoW) configuration, a die-on-wafer configuration, a die-on-die configuration, and/or another direct bonding configuration.

The bonding operation may be performed after frontside processing of the semiconductor device 102 to form the IC devices 112, the interconnect layer 106 (e.g., the frontside interconnect layer including the dielectric layer(s) 114, the conductive structures 116, the bonding pads 118, and the bonding vias 120), and the through-substrate interconnect structure 128 as described in connection with FIGS. 2A-2M and/or 4A-4H. Similar operations as described in connection with FIGS. 2A-2M and/or 4A-4H may be performed to form the semiconductor device 504 prior to bonding.

A bonding tool may be used to perform the bonding operation to bond the semiconductor devices 102 and 504 at the bonding interface 506. The bonding operation may include forming a direct bond between the semiconductor devices 102 and 504 through a direct physical connection of the bonding pads 118 of the semiconductor device 102 with the bonding pads 520 of the semiconductor device 504 (e.g., direct metal-to-metal bonds), and through a direct physical connection of a dielectric layer 114 of the semiconductor device 102 with the dielectric layer 516 of the semiconductor device 504 (e.g., direct dielectric-to-dielectric bonds). In this way, the interconnect layer 106 on the frontside of the semiconductor device 102 and the interconnect layer 510 on the frontside of the semiconductor device 504 may be facing each other in the semiconductor package 502.

As shown in FIGS. 6C and 6D, backside processing may be performed for the semiconductor device 102 after the semiconductor devices 102 and 504 are bonded together. Such operations may include similar operations as described in connection with FIGS. 2M-2P and/or 4I-4K.

For example, and as shown in FIG. 6C, a wafer grinding operation may be performed on the backside of the semiconductor layer 110 to reduce the thickness of the semiconductor layer 110. A grinding tool may be used to remove material from the semiconductor layer 110 by wafer grinding. The grinding operation may be stopped after the bottom of the through-substrate interconnect structure 128 is exposed through the backside of the semiconductor layer 110. Thus, the portions of the liners 302 on the bottom of the through-substrate interconnect structure 128 may be removed, leaving behind portions of the liners 302 on the sidewalls of the through-substrate interconnect structure 128. Removal of the liners 302 from the bottom of the through-substrate interconnect structure 128 enables a conductive structure 124 of the interconnect layer 108 to be formed on the bottom of the through-substrate interconnect structure 128, as shown in FIG. 6D, which enables a low contact resistance to be achieved between the conductive structure 124 and the through-substrate interconnect structure 128.

As indicated above, FIGS. 6A-6D are provided as an example. Other examples may differ from what is described with regard to FIGS. 6A-6D.

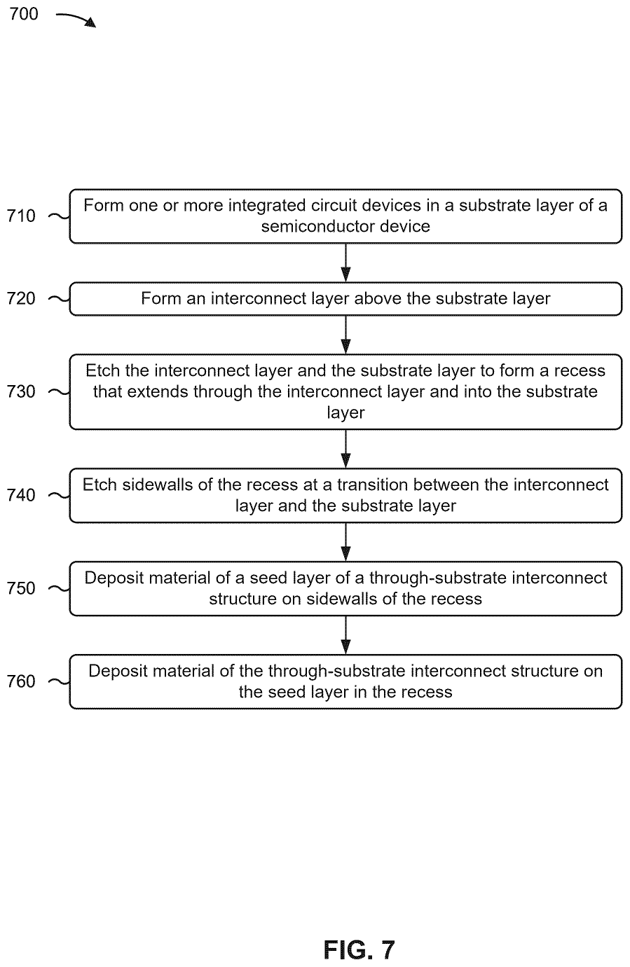

FIG. 7 is a flowchart of an example process 700 associated with forming a semiconductor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming one or more integrated circuit devices in a substrate layer of a semiconductor device (block 710). For example, one or more semiconductor processing tools may be used to form one or more integrated circuit devices (e.g., IC devices 112) in a substrate layer (e.g., a semiconductor layer 110) of a semiconductor device (e.g., a semiconductor device 102), as described herein.

As further shown in FIG. 7, process 700 may include forming an interconnect layer above the substrate layer (block 720). For example, one or more semiconductor processing tools may be used to form an interconnect layer (e.g., an interconnect layer 106) above the substrate layer, as described herein.

As further shown in FIG. 7, process 700 may include etching the interconnect layer and the substrate layer to form a recess that extends through the interconnect layer and into the substrate layer (block 730). For example, one or more semiconductor processing tools may be used to etch the interconnect layer and the substrate layer to form a recess (e.g., a recess 206) that extends through the interconnect layer and into the substrate layer, as described herein.

As further shown in FIG. 7, process 700 may include etching sidewalls of the recess at a transition between the interconnect layer and the substrate layer (block 740). For example, one or more semiconductor processing tools may be used to etch sidewalls of the recess at a transition (e.g., a transition 210) between the interconnect layer and the substrate layer, as described herein.

As further shown in FIG. 7, process 700 may include depositing material of a seed layer of a through-substrate interconnect structure on sidewalls of the recess (block 750). For example, one or more semiconductor processing tools may be used to deposit material of a seed layer (e.g., a seed layer 402) of a through-substrate interconnect structure (e.g., a through-substrate interconnect structure 128) on sidewalls of the recess, as described herein.

As further shown in FIG. 7, process 700 may include depositing material of the through-substrate interconnect structure on the seed layer in the recess (block 760). For example, one or more semiconductor processing tools may be used to deposit material of the through-substrate interconnect structure on the seed layer in the recess, as described herein.

Process 700 may include additional implementations, such as any single implementation or any combination of implementations described below and/or in connection with one or more other processes described elsewhere herein.

In a first implementation, etching the interconnect layer and the substrate layer to form the recess includes performing a first etch operation to etch the interconnect layer to form the recess into the interconnect layer to the transition between the interconnect layer and the substrate layer, and performing, after the first etch operation, a second etch operation to etch the substrate layer to extend the recess into the substrate layer.

In a second implementation, alone or in combination with the first implementation, lateral etching of the substrate layer at the transition between the interconnect layer and the substrate layer occurs in the second etch operation and results in formation of a kink in the recess at the transition between the interconnect layer and the substrate layer, and etching sidewalls of the recess includes performing a third etch operation to etch the kink at the transition between the interconnect layer and the substrate layer.

In a third implementation, alone or in combination with one or more of the first and second implementations, lateral etching of the substrate layer at the transition between the interconnect layer and the substrate layer in the second etch operation results in formation of a bowed section (e.g., a bowed section 134) in the recess below the transition between the interconnect layer and the substrate layer.

In a fourth implementation, alone or in combination with one or more of the first through third implementations, a first lateral width (e.g., a dimension D5) of the recess in the bowed section is greater than a second lateral width (e.g., a dimension D4) at the transition between the interconnect layer and the substrate layer, and etching sidewalls of the recess includes performing a third etch operation to etch the sidewalls of the recess through interconnect layer to decrease a difference between the first lateral width and the second lateral width.

In a fifth implementation, alone or in combination with one or more of the first through fourth implementations, an outside angle (e.g., a dimension D6) between a first portion of the sidewalls of the recess in the bowed section and a second portion (e.g., a tapered section 212) of the sidewalls in the interconnect layer is less than approximately 140 degrees prior to the third etch operation, and the outside angle (e.g., a dimension D9) is greater than approximately 170 degrees after the third etch operation.

In a sixth implementation, alone or in combination with one or more of the first through fifth implementations, process 700 includes depositing material of one or more liners (e.g., liners 302, such as a liner 304, a liner 306, a liner 308, and/or a liner 310) on the sidewalls of the recess, where depositing the material of the seed layer includes depositing the material of the seed layer on the one or more liners.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

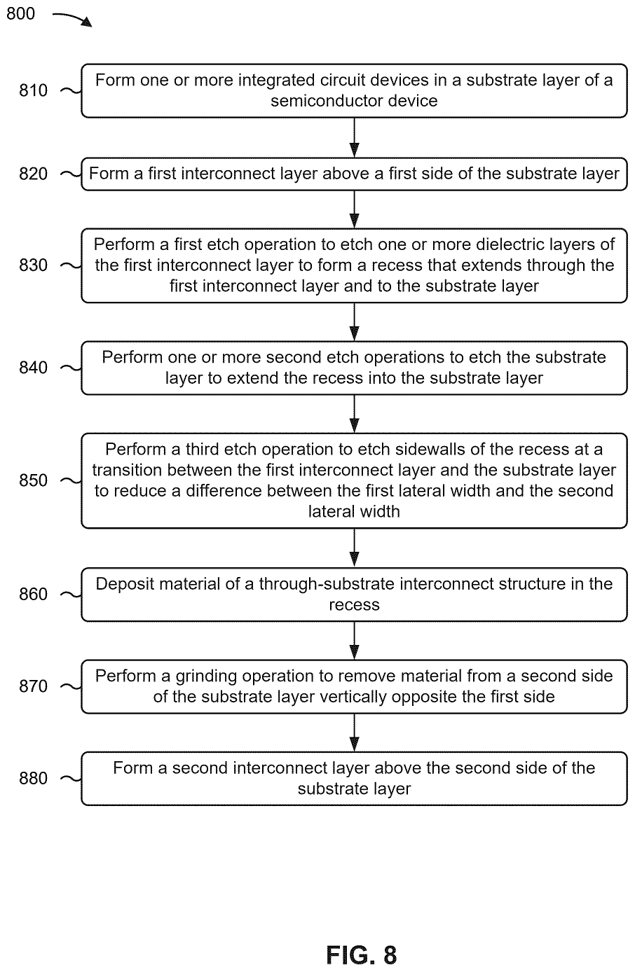

FIG. 8 is a flowchart of an example process 800 associated with forming a semiconductor device described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming one or more integrated circuit devices in a substrate layer of a semiconductor device (block 810). For example, one or more semiconductor processing tools may be used to form one or more integrated circuit devices (e.g., one or more IC devices 112) in a substrate layer (e.g., a semiconductor layer 110) of a semiconductor device (e.g., a semiconductor device 102), as described herein.

As further shown in FIG. 8, process 800 may include forming a first interconnect layer above a first side of the substrate layer (block 820). For example, one or more semiconductor processing tools may be used to form a first interconnect layer (e.g., an interconnect layer 106) above a first side (e.g., a frontside) of the substrate layer, as described herein.

As further shown in FIG. 8, process 800 may include performing a first etch operation to etch one or more dielectric layers of the first interconnect layer to form a recess that extends through the first interconnect layer and to the substrate layer (block 830). For example, one or more semiconductor processing tools may be used to perform a first etch operation to etch one or more dielectric layers (e.g., one or more dielectric layers 114) of the first interconnect layer to form a recess (e.g., a recess 206) that extends through the first interconnect layer and to the substrate layer, as described herein.

As further shown in FIG. 8, process 800 may include performing one or more second etch operations to etch the substrate layer to extend the recess into the substrate layer (block 840). For example, one or more semiconductor processing tools may be used to perform one or more second etch operations to etch the substrate layer to extend the recess into the substrate layer, as described herein. In some implementations, after the one or more second etch operations, a first lateral width (e.g., dimension D5) of the recess below a top of the substrate layer is greater than a second lateral width (e.g., dimension D4) of the recess at a bottom of the first interconnect layer.

As further shown in FIG. 8, process 800 may include performing a third etch operation to etch sidewalls of the recess at a transition between the first interconnect layer and the substrate layer to reduce a difference between the first lateral width and the second lateral width (block 850). For example, one or more semiconductor processing tools may be used to perform a third etch operation to etch sidewalls of the recess at a transition (e.g., a transition 210) between the first interconnect layer and the substrate layer to reduce a difference between the first lateral width and the second lateral width, as described herein.

As further shown in FIG. 8, process 800 may include depositing material of a through-substrate interconnect structure in the recess (block 860). For example, one or more semiconductor processing tools may be used to deposit material of a through-substrate interconnect structure (e.g., a through-substrate interconnect structure 128) in the recess, as described herein.

As further shown in FIG. 8, process 800 may include performing a grinding operation to remove material from a second side of the substrate layer vertically opposite the first side (block 870). For example, one or more semiconductor processing tools may be used to perform a grinding operation to remove material from a second side of the substrate layer vertically opposite the first side, as described herein.

As further shown in FIG. 8, process 800 may include forming a second interconnect layer above the second side of the substrate layer (block 880). For example, one or more semiconductor processing tools may be used to form a second interconnect layer (e.g., an interconnect layer 108) above the second side (e.g., the backside) of the substrate layer, as described herein.

Process 800 may include additional implementations, such as any single implementation or any combination of implementations described below and/or in connection with one or more other processes described elsewhere herein.

In a first implementation, performing a third etch operation includes performing a third etch operation to increase the second lateral width of the recess at the bottom of the first interconnect layer to a third lateral width (e.g., a dimension D7).

In a second implementation, alone or in combination with the first implementation, increasing the second lateral width of the recess at the bottom of the first interconnect layer to the third lateral width results in an increase in an outer angle (e.g., a dimension D6 to a dimension D9) between a first section (e.g., a bowed section 214) of the sidewalls of the recess at the top of the substrate layer and a second section (e.g., a tapered section 212) of the sidewalls of the recess at the bottom of the first interconnect layer.

In a third implementation, alone or in combination with one or more of the first and second implementations, process 800 includes depositing the material of a seed layer (e.g., a seed layer 402) in the recess such that the seed layer is continuous through the transition between the first interconnect layer and the substrate layer.

In a fourth implementation, alone or in combination with one or more of the first through third implementations, performing the third etch operation includes performing a plasma etch operation using a plasma power that is included in a range of approximately 1000 watts to approximately 3000 watts.

In a fifth implementation, alone or in combination with one or more of the first through fourth implementations, performing the third etch operation includes performing a plasma etch operation using a bias voltage that is included in a range of approximately 200 volts to approximately 800 volts.

In a sixth implementation, alone or in combination with one or more of the first through fifth implementations, performing the third etch operation includes performing the third etch operation using a fluorocarbon gas.

In a seventh implementation, alone or in combination with one or more of the first through sixth implementations, where the fluorocarbon gas includes at least one of a tetrafluoromethane (CF₄) gas, an octafluorocyclobutane (C₄F₈) gas, or a sulfur hexafluoride (SF₆) gas.

In an eighth implementation, alone or in combination with one or more of the first through seventh implementations, performing the third etch operation includes performing a plasma etch operation using an oxygen (O₂) plasma and the fluorocarbon gas to generate fluorine radicals that etch the one or more dielectric layers of the first interconnect layer at a faster rate than a semiconductor material of the substrate layer.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a recess for a through-substrate interconnect structure is formed through an interconnect layer and into a substrate layer of a semiconductor device in a manner that decreases the sharpness of a transition angle (e.g., a kink) in the sidewalls of the recess between the interconnect layer and the substrate layer. After the substrate layer is etched to extend the recess into the substrate layer, a subsequent sidewall trimming operation is performed. The trimming operation may include a highly directional (e.g., vertical) etch that is performed to trim the sidewalls of the recess at or near the transition between the interconnect layer and the substrate layer. The trimming operation flattens out the kink in the sidewalls, thereby decreasing the sharpness of the transition angle in the sidewalls of the recess between the interconnect layer and the substrate layer. The increased flatness of the sidewalls increases the coverage of a seed layer that is subsequently deposited on the sidewalls of the recess, which reduces the likelihood of void formation in the bulk material layer of the through-substrate interconnect structure that is subsequently deposited on the seed layer in the recess. The reduced likelihood of void formation may enable a low electrical resistance to be achieved for the through-substrate interconnect structure, thereby increasing the performance of the semiconductor device. As semiconductor processing nodes advance, and the sizes of through-substrate interconnect structures are reduced, the reduced likelihood of void formation may decrease the likelihood of discontinuity formation in the through-substrate interconnect structures of semiconductor devices, thereby increasing the yield of the semiconductor devices formed on a semiconductor substrate.

As described in greater detail above, some implementations described herein provide a method. The method includes forming one or more integrated circuit devices in a substrate layer of a semiconductor device. The method includes forming an interconnect layer above the substrate layer. The method includes etching the interconnect layer and the substrate layer to form a recess that extends through the interconnect layer and into the substrate layer. The method includes etching sidewalls of the recess at a transition between the interconnect layer and the substrate layer. The method includes depositing material of a seed layer of a through-substrate interconnect structure on sidewalls of the recess. The method includes depositing material of the through-substrate interconnect structure on the seed layer in the recess.

As described in greater detail above, some implementations described herein provide a method. The method includes forming one or more integrated circuit devices in a substrate layer of a semiconductor device. The method includes forming a first interconnect layer above a first side of the substrate layer. The method includes performing a first etch operation to etch one or more dielectric layers of the first interconnect layer to form a recess that extends through the first interconnect layer and to the substrate layer. The method includes performing one or more second etch operations to etch the substrate layer to extend the recess into the substrate layer, where, after the one or more second etch operations, a first lateral width of the recess below a top of the substrate layer is greater than a second lateral width of the recess at a bottom of the first interconnect layer. The method includes performing a third etch operation to etch sidewalls of the recess at a transition between the first interconnect layer and the substrate layer to reduce a difference between the first lateral width and the second lateral width. The method includes depositing material of a through-substrate interconnect structure in the recess. The method includes performing a grinding operation to remove material from a second side of the substrate layer vertically opposite the first side. The method includes forming a second interconnect layer above the second side of the substrate layer.

As described in greater detail above, some implementations described herein provide a semiconductor device. The semiconductor device includes a semiconductor layer. The semiconductor device includes one or more integrated circuit devices in the semiconductor layer. The semiconductor device includes a first interconnect layer vertically adjacent to a first side of the semiconductor layer. The semiconductor device includes a second interconnect layer vertically adjacent to a second side of the semiconductor layer opposing the first side. The semiconductor device includes a through-substrate interconnect structure extending through the semiconductor layer between the first interconnect layer and the second interconnect layer, where a first lateral width of the through-substrate interconnect structure at a transition between the first interconnect layer and the semiconductor layer is less than a second lateral width of a bowed section of the through-substrate interconnect structure in the semiconductor layer, and where a ratio of the second lateral width and the first lateral width is included in a range of approximately 1:0.86 to approximately 1:0.99.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more integrated circuit devices in a substrate layer of a semiconductor device;
forming an interconnect layer above the substrate layer;
etching the interconnect layer and the substrate layer to form a recess that extends through the interconnect layer and into the substrate layer;
etching sidewalls of the recess at a transition between the interconnect layer and the substrate layer;
depositing material of a seed layer of a through-substrate interconnect structure on sidewalls of the recess; and
depositing material of the through-substrate interconnect structure on the seed layer in the recess.

2. The method of claim 1, wherein etching the interconnect layer and the substrate layer to form the recess comprises:
performing a first etch operation to etch the interconnect layer to form the recess into the interconnect layer to the transition between the interconnect layer and the substrate layer; and
performing, after the first etch operation, a second etch operation to etch the substrate layer to extend the recess into the substrate layer.

3. The method of claim 2, wherein lateral etching of the substrate layer at the transition between the interconnect layer and the substrate layer occurs in the second etch operation and results in formation of a kink in the recess at the transition between the interconnect layer and the substrate layer; and
wherein etching sidewalls of the recess comprises:
performing a third etch operation to etch the kink at the transition between the interconnect layer and the substrate layer.

4. The method of claim 2, wherein lateral etching of the substrate layer at the transition between the interconnect layer and the substrate layer in the second etch operation results in formation of a bowed section in the recess below the transition between the interconnect layer and the substrate layer.

5. The method of claim 4, wherein a first lateral width of the recess in the bowed section is greater than a second lateral width at the transition between the interconnect layer and the substrate layer; and
wherein etching sidewalls of the recess comprises:
performing a third etch operation to etch the sidewalls of the recess through interconnect layer to decrease a difference between the first lateral width and the second lateral width.

6. The method of claim 5, wherein an outside angle between a first portion of the sidewalls of the recess in the bowed section and a second portion of the sidewalls in the interconnect layer is less than approximately 140 degrees prior to the third etch operation; and
wherein the outside angle is greater than approximately 170 degrees after the third etch operation.

7. The method of claim 1, further comprising:
depositing material of one or more liners on the sidewalls of the recess,
wherein depositing the material of the seed layer comprises:
depositing the material of the seed layer on the one or more liners.

8. A method, comprising:
forming one or more integrated circuit devices in a substrate layer of a semiconductor device;
forming a first interconnect layer above a first side of the substrate layer;
performing a first etch operation to etch one or more dielectric layers of the first interconnect layer to form a recess that extends through the first interconnect layer and to the substrate layer;
performing one or more second etch operations to etch the substrate layer to extend the recess into the substrate layer,
wherein, after the one or more second etch operations, a first lateral width of the recess below a top of the substrate layer is greater than a second lateral width of the recess at a bottom of the first interconnect layer;
performing a third etch operation to etch sidewalls of the recess at a transition between the first interconnect layer and the substrate layer to reduce a difference between the first lateral width and the second lateral width;
depositing material of a through-substrate interconnect structure in the recess;
performing a grinding operation to remove material from a second side of the substrate layer vertically opposite the first side; and
forming a second interconnect layer above the second side of the substrate layer.

9. The method of claim 8, the wherein performing the third etch operation comprises:
performing the third etch operation to increase the second lateral width of the recess at the bottom of the first interconnect layer to a third lateral width.

10. The method of claim 9, wherein increasing the second lateral width of the recess at the bottom of the first interconnect layer to the third lateral width results in an increase in an outer angle between a first section of the sidewalls of the recess at the top of the substrate layer and a second section of the sidewalls of the recess at the bottom of the first interconnect layer.

11. The method of claim 8, further comprising:
depositing the material of a seed layer in the recess such that the seed layer is continuous through the transition between the first interconnect layer and the substrate layer.

12. The method of claim 8, wherein performing the third etch operation comprises:
performing a plasma etch operation using a plasma power that is included in a range of approximately 1000 watts to approximately 3000 watts.

13. The method of claim 8, wherein performing the third etch operation comprises:
performing a plasma etch operation using a bias voltage that is included in a range of approximately 200 volts to approximately 800 volts.

14. The method of claim 8, wherein performing the third etch operation comprises:
performing the third etch operation using a fluorocarbon gas.

15. The method of claim 14, wherein the fluorocarbon gas comprises at least one of:
a tetrafluoromethane (CF₄) gas,
an octafluorocyclobutane (C₄F₈) gas, or
a sulfur hexafluoride (SF₆) gas.

16. The method of claim 15, wherein performing the third etch operation comprises:
performing a plasma etch operation using an oxygen (O₂) plasma and the fluorocarbon gas to generate fluorine radicals that etch the one or more dielectric layers of the first interconnect layer at a faster rate than a semiconductor material of the substrate layer.

17. A semiconductor device, comprising:
a semiconductor layer;
one or more integrated circuit devices in the semiconductor layer;
a first interconnect layer vertically adjacent to a first side of the semiconductor layer;
a second interconnect layer vertically adjacent to a second side of the semiconductor layer opposing the first side; and
a through-substrate interconnect structure extending through the semiconductor layer between the first interconnect layer and the second interconnect layer,
wherein a first lateral width of the through-substrate interconnect structure at a transition between the first interconnect layer and the semiconductor layer is less than a second lateral width of a bowed section of the through-substrate interconnect structure in the semiconductor layer, and
wherein a ratio of the second lateral width and the second lateral width is included in a range of approximately 1:0.86 to approximately 1:0.99.

18. The semiconductor device of claim 17, wherein an outside angle between a first sidewall section of the bowed section of the through-substrate interconnect structure and a second sidewall section of the through-substrate interconnect structure at the transition between the first interconnect layer and the semiconductor layer is included in a range of approximately 170 degrees to approximately 178 degrees.

19. The semiconductor device of claim 17, wherein a difference between the second lateral width and the first lateral width are each included in a range of approximately 0 microns to approximately 0.3 microns.

20. The semiconductor device of claim 17, further comprising:
one or more liners along sidewalls of the through-substrate interconnect structure.
